(19) United States
(12) Patent Application Publication
(10) Pub. No.: US 2026/0055280 A1
(43) Pub. Date: Feb. 26, 2026

(54) RADIATION SENSITIVE COMPOSITIONS COMPRISING A COMBINATION OF METALS OR METALLOID COMPOUNDS

(71) Applicant: ISP Investments LLC, Wilmington, DE (US)

(72) Inventors: David K. HOOD, Basking Ridge, NJ (US); OSAMA M. MUSA, Bedminster, NJ (US)

(73) Assignee: ISP Investments LLC, Wilmington, DE (US)

(21) Appl. No.: 18/698,298

(22) PCT Filed: Oct. 4, 2022
(86) PCT No.: PCT/US2022/045614

§ 371 Date: Apr. 3, 2024

Related U.S. Application Data
(60) Provisional application No. 63/254,336, filed on Oct. 11, 2021.

(51) Int. Cl. C09D 5/32; C09D 7/61; G03F 7/004

(52) U.S. Cl. CPC C09D 5/32; C09D 7/61; G03F 7/0043

(57) ABSTRACT

The invention provides radiation sensitive compositions and substrates coated with radiation sensitive compositions wherein the composition comprises a combination of metals and/or metalloid compounds, a functionalized or unfunctionalized acetylenic compound, and other optional ingredients such as amelioration agents. The invention further provides radiation sensitive devices for detection or measurement of radiation comprising substrates coated with these radiation sensitive compositions. The radiation sensitive compositions and devices have applications in dentistry, non-destructive testing, oncology, radiology, and radiotherapy, among others.

### BACKGROUND

### Field of the Invention

The disclosed and/or claimed inventive concept(s) provides radiation sensitive compositions.

### Description of Related Art

In facilities where radiation sources are used, for example, in hospitals where cancer patients receive radiation treatments or in blood banks where blood products are irradiated, various methods are used to quantitatively determine the radiation exposure. The methods practiced include the use of thermoluminescent dosimeters (TLD's), ionization-type radiation detectors, photographic film, and radiochromic materials. TLD's are inconvenient because they require a complicated and time-consuming read-out process. Ionization-type radiation detectors are awkward and unwieldy and require a complicated setup. Photographic film requires a time-consuming chemical processing procedure before read-out. In case of radiochromic materials, the calculation of the dose requires a complex sequence of steps.

Photochromic polyacetylenes responsive to radiation exposure have been disclosed in several U.S. Patents, namely U.S. Pat. Nos. 4,066,676; 4,581,315; 3,501,302; 3,501,297; 3,501,303; 3,501,308; 3,772,028; 3,844,791, and 3,954,816. The recording of image or dosage information using these polyacetylene compounds has presented several problems and shortcomings including an inadequate degree of resolution, clarity, color instability of an imaged pattern. Other deficiencies include a relatively slow image development, and, in some cases, the impractical need to image at extremely low temperatures or at excessively high dosage levels.

A preferred radiation sensitive material in radiation dosimeters includes dispersions of crystalline 10,12-pentacosadiynoic acid (PCDA). Subjecting monomeric PCDA crystals to ionizing radiation results in progressive polymerization, the degree of polymerization increasing with radiation dose. The amount of polymerization (and hence, the radiation dose) can be determined by measuring either the optical density or the spectral absorption of the exposed dosimeter. However, it has been found that these parameters also vary with both the temperature of the device when measured as well as the thickness of PCDA dispersion. Maximum accuracy of dose measurement must account for the temperature and thickness effects.

Radiation dosimetry film provides a means for measuring radiation exposure at a point, but its principal utility is in obtaining a two-dimensional map of radiation exposure, i.e. radiation exposure at multiple points in a two-dimensional array. A typical user may measure an 8″×10″ size film at a spatial resolution of 75 dpi, generating a map of radiation doses at 450,000 points. Of course, other resolutions can be used to generate the radiation exposure map.

U.S. Pat. No. 5,637,876 discloses a radiation dosimeter, exemplarily for use in determining a level of radiation to which a patient is subjected during radiation treatment, which comprises a substrate provided with a layer of radiation sensitive material. The radiation sensitive material has an optical density which varies systematically in accordance with the degree of radiation exposure. The dosimeter may take the form of a card or a flexible substrate which is positionable on the patient or other irradiation subject and which is also positionable in, or slidable through a slot in, a dose reader which includes a reflection or transmission densitometer.

Muthamma et al. in Journal of Applied Polymer Science, 2019, volume 136 (37), 47949, have investigated the efficacy of poly(vinyl alcohol)-bismuth oxide composites as radiation shielding materials. Poly(vinyl alcohol) composites with different weight percentages of bismuth were prepared by a simple solution casting technique. Thermogravimetric analysis (TGA) revealed an enhanced thermal stability of these composites.

Jamil et al. in Radiation Physics and Chemistry, Volume 156, 2019, 272-282, have fabricated electrospun poly(vinyl alcohol)-bismuth oxide and poly(vinyl alcohol)-tungsten trioxide nanofibre mats with different concentrations of PVA. The X-ray shielding criteria such as density, thickness, and mass attenuation coefficient of the fabricated electrospun samples were studied to investigate their performance as a potential X-ray shielding material.

Abunahel et al. in Applied Physics A, Volume 124, 2018, 828, have studied the X-ray attenuation by 2 mm matrix composites of epoxy-polyvinyl alcohol filled with different percentages of bismuth oxide nanoparticles using mammography and general radiography units.

It has been found that compositions according to the disclosed and/or claimed inventive concept(s) have superior properties that enable them to be used as radiation sensitive materials in radiation sensitive devices for detection and measurement of high energy radiation such as chemosensors, biosensors, and dosimeters in several industrial and healthcare applications. These compounds and compositions have excellent energy sensitivity towards a broad range of energy sources such as heat, electromagnetic radiation, ionizing radiation, gamma rays, UV rays, infrared rays, visible radiation, and X-rays.

### SUMMARY

In a first aspect, the disclosed and/or claimed inventive concept(s) provides a radiation sensitive coating composition comprising a component (a) and a component (b) wherein the component (a) is a metal compound or a metalloid compound and the component (b) is at least one different metal compound or metalloid compound.

In a second aspect, the disclosed and/or claimed inventive concept(s) provides a radiation sensitive composition comprising a component (a), a component (b), and a component (c) wherein the component (a) is a metal compound or a metalloid compound, the component (b) is at least one different metal compound or metalloid compound, and the component (c) is at least one functionalized or unfunctionalized acetylenic compound.

In a third aspect, the disclosed and/or claimed inventive concept(s) provides a radiation sensitive composition comprising a component (a), a component (b), a component (c), and a component (d) wherein the component (a) is a metal compound or a metalloid compound, the component (b) is at least one different metal compound or metalloid compound, the component (c) is at least one functionalized or unfunctionalized acetylenic compound, and the component (d) is at least one amelioration agent.

In a fourth aspect, the disclosed and/or claimed inventive concept(s) provides a substrate coated with a radiation sensitive composition comprising a component (a), a component (b), a component (c), and a component (d) wherein the component (a) is a metal compound or a metalloid compound, the component (b) is at least one different metal compound or metalloid compound, the component (c) is at least one functionalized or unfunctionalized acetylenic compound, and the component (d) is at least one amelioration agent.

In a fifth aspect, the disclosed and/or claimed inventive concept(s) provides a radiation sensitive device for detection or measurement of radiation comprising a substrate coated with a radiation sensitive composition comprising a component (a), a component (b), a component (c), and a component (d) wherein the component (a) is a metal compound or a metalloid compound, the component (b) is at least one different metal compound or metalloid compound, the component (c) is at least one functionalized or unfunctionalized acetylenic compound, and the component (d) is at least one amelioration agent.

In a sixth aspect, the disclosed and/or claimed inventive concept(s) provides a method for coating a radiation sensitive composition comprising the steps of selecting a substrate that is compatible with the composition, preparing the substrate for said composition to be applied onto it, applying the composition on said substrate after the step of preparing, optionally exposing the substrate after the step of applying, and optionally developing the substrate after the step of exposing, wherein the radiation sensitive composition comprises a component (a), a component (b), a component (c), and a component (d) wherein the component (a) is a metal compound or a metalloid compound, the component (b) is at least one different metal compound or metalloid compound, the component (c) is at least one functionalized or unfunctionalized acetylenic compound, and the component (d) is at least one amelioration agent.

In a seventh aspect, the disclosed and/or claimed inventive concept(s) provides a process for preparing a printable substrate comprising the steps of providing a substrate, optionally applying on the substrate a layer serving as a base layer, applying on the substrate or the base layer at least one layer of a radiation sensitive composition comprising a component (a), a component (b), a component (c), and a component (d) wherein the component (a) is a metal compound or a metalloid compound, the component (b) is at least one different metal compound or metalloid compound, the component (c) is at least one functionalized or unfunctionalized acetylenic compound, and the component (d) is at least one amelioration agent.

### DETAILED DESCRIPTION

Before explaining at least one aspect of the disclosed and/or claimed inventive concept(s) in detail, it is to be understood that the disclosed and/or claimed inventive concept(s) is not limited in its application to the details of construction and the arrangement of the components or steps or methodologies set forth in the following description or illustrated in the drawings. The disclosed and/or claimed inventive concept(s) is capable of other aspects or of being practiced or carried out in various ways. Also, it is to be understood that the phraseology and terminology employed herein is for the purpose of description and should not be regarded as limiting.

Unless otherwise defined herein, technical terms used in connection with the disclosed and/or claimed inventive concept(s) shall have the meanings that are commonly understood by those of ordinary skill in the art. Further, unless otherwise required by context, singular terms shall include pluralities and plural terms shall include the singular.

All patents, published patent applications, and non-patent publications referenced in any portion of this application are herein expressly incorporated by reference in their entirety to the same extent as if each individual patent or publication was specifically and individually indicated to be incorporated by reference.

All articles and/or methods disclosed herein can be made and executed without undue experimentation based on the present disclosure. While the articles and methods of the disclosed and/or claimed inventive concept(s) have been described in terms of aspects, it will be apparent to those of ordinary skill in the art that variations may be applied to the articles and/or methods and in the steps or in the sequence of steps of the method described herein without departing from the concept, spirit and scope of the disclosed and/or claimed inventive concept(s). All such similar substitutes and modifications apparent to those skilled in the art are deemed to be within the spirit, scope, and concept of the disclosed and/or claimed inventive concept(s).

As utilized in accordance with the disclosure, the following terms, unless otherwise indicated, shall be understood to have the following meanings.

The use of the word “a” or “an” when used in conjunction with the term “comprising” may mean “one,” but it is also consistent with the meaning of “one or more,” “at least one,” and “one or more than one.” The use of the term “or” is used to mean “and/or” unless explicitly indicated to refer to alternatives only if the alternatives are mutually exclusive, although the disclosure supports a definition that refers to only alternatives and “and/or.”

Throughout this application, the term “about” is used to indicate that a value includes the inherent variation of error for the quantifying device, the method being employed to determine the value, or the variation that exists among the study subjects. For example, but not by way of limitation, when the term “about” is utilized, the designated value may vary by plus or minus twelve percent, or eleven percent, or ten percent, or nine percent, or eight percent, or seven percent, or six percent, or five percent, or four percent, or three percent, or two percent, or one percent.

The use of the term “at least one” will be understood to include one as well as any quantity more than one, including but not limited to, 1, 2, 3, 4, 5, 10, 15, 20, 30, 40, 50, 100, etc. The term “at least one” may extend up to 100 or 1000 or more depending on the term to which it is attached. In addition, the quantities of 100/1000 are not to be considered limiting as lower or higher limits may also produce satisfactory results. In addition, the use of the term “at least one of X, Y, and Z” will be understood to include X alone, Y alone, and Z alone, as well as any combination of X, Y, and Z. The use of ordinal number terminology (i.e., “first”, “second”, “third”, “fourth”, etc.) is solely for the purpose of differentiating between two or more items and, unless otherwise stated, is not meant to imply any sequence or order or importance to one item over another or any order of addition.

As used herein, the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps. The term “or combinations thereof” as used herein refers to all permutations and combinations of the listed items preceding the term. For example, “A, B_{Xn}, B_{Xn+1}, or combinations thereof” is intended to include at least one of: A, B_{Xn}, B_{Xn+1}, AB_{Xn}, A B_{Xn+1}, B_{Xn}B_{Xn+1}, or AB_{Xn}B_{Xn+1} and, if order is important in a particular context, also B_{Xn}A, B_{Xn+1}A, B_{Xn+1}B_{Xn}, B_{Xn+1}B_{Xn}A, B_{Xn}B_{Xn+1}A, AB_{Xn+1}B_{Xn}, B_{Xn}AB_{Xn+1}, or B_{Xn+1}AB_{Xn}. Continuing with this example, expressly included are combinations that contain repeats of one or more item or term, such as B_{Xn}B_{Xn}, AAA, MB_{Xn}, B_{Xn}B_{Xn}B_{Xn+1}, AAAB_{Xn}B_{Xn+1}B_{Xn+1}B_{Xn+1}B_{Xn-1}, B_{Xn+1}B_{Xn}B_{Xn}AAA, B_{Xn+1}A B_{Xn}AB_{Xn}B_{Xn}, and so forth. The skilled artisan will understand that typically there is no limit on the number of items or terms in any combination, unless otherwise apparent from the context.

The term “each independently selected from the group consisting of” means when a group appears more than once in a structure, that group may be selected independently each time it appears.

The term “hydrocarbyl” includes straight-chain and branched-chain alkyl, alkenyl, alkynyl, cycloalkyl, cycloalkenyl, aryl groups, and combinations thereof with optional heteroatom(s). A hydrocarbyl group may be mono-, di- or polyvalent.

The term “alkyl” refers to a functionalized or unfunctionalized, monovalent, straight-chain, branched-chain, or cyclic C₁-C₆₀ hydrocarbyl group optionally having one or more heteroatoms. In one non-limiting embodiment, an alkyl is a C₁-C₄₅ hydrocarbyl group. In another non-limiting embodiment, an alkyl is a C₁-C₃₀ hydrocarbyl group. Non-limiting examples of alkyl include methyl, ethyl, n-propyl, isopropyl, n-butyl, isobutyl, tert-butyl, n-pentyl, isopentyl, n-hexyl, n-heptyl, n-octyl, 2-ethylhexyl, tert-octyl, iso-norbornyl, n-dodecyl, tert-dodecyl, n-tetradecyl, n-hexadecyl, n-octadecyl, n-eicosyl, cyclobutyl, cyclopentyl, cyclohexyl, and the like. The definition of “alkyl” also includes groups obtained by combinations of straight-chain, branched-chain and/or cyclic structures.

The term “aryl” refers to a functionalized or unfunctionalized, monovalent, aromatic hydrocarbyl group optionally having one or more heteroatoms. The definition of aryl includes carbocyclic and heterocyclic aromatic groups. Non-limiting examples of aryl groups include phenyl, naphthyl, indenyl, indanyl, azulenyl, fluorenyl, anthracenyl, furyl, thienyl, pyridyl, pyrrolyl, oxazolyl, thiazolyl, imidazolyl, pyrazolyl, 2-pyrazolinyl, pyrazolidinyl, isoxazolyl, isothiazolyl, 1,2,3-oxadiazolyl, 1,2,3-triazolyl, 1,3,4-thiadiazolyl, pyridazinyl, pyrimidinyl, pyrazinyl, 1,3,5-triazinyl, 1,3,5-trithianyl, indolizinyl, indolyl, isoindolyl, 3H-indolyl, indolinyl, benzo[b]furanyl, 2,3-dihydrobenzofuranyl, benzo[b]thiophenyl, 1H-indazolyl, benzimidazolyl, benzthiazolyl, purinyl, 4H-quinolizinyl, isoquinolinyl, cinnolinyl, phthalazinyl, quinazolinyl, quinoxalinyl, 1,8-naphthridinyl, pteridinyl, carbazolyl, acridinyl, phenazinyl, phenothiazinyl, phenoxyazinyl, pyrazolo[1,5-c]triazinyl, and the like.

The term “aralkyl” refers to an alkyl group comprising one or more aryl substituent(s) wherein “aryl” and “alkyl” are as defined above. Non-limiting examples of aralkyl groups include benzyl, 2-phenyl-ethyl, 3-phenyl-propyl, 4-phenyl-butyl, 5-phenyl-pentyl, 4-phenylcyclohexyl, 4-benzylcyclohexyl, 4-phenylcyclohexylmethyl, 4-benzylcyclohexylmethyl, and the like.

The term “alkylene” refers to a functionalized or unfunctionalized, divalent, straight-chain, branched-chain, or cyclic C₁-C₄₀ hydrocarbyl group optionally having one or more heteroatoms. In one non-limiting embodiment, an alkylene is a C₁-C₃₀ group. In another non-limiting embodiment, an alkylene is a C₁-C₂₀ group. Non-limiting examples of alkylene groups include:

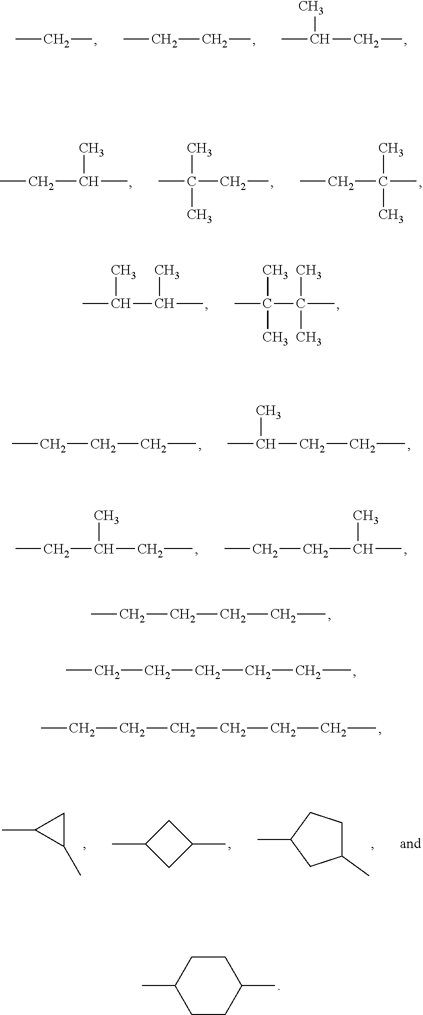

The term “arylene” refers to a functionalized or unfunctionalized, divalent, aromatic hydrocarbyl group optionally having one or more heteroatoms. The definition of arylene includes carbocyclic and heterocyclic groups. Non-limiting examples of arylene groups include phenylene, naphthylene, pyridinylene, and the like.

The term “heteroatom” refers to oxygen, nitrogen, sulfur, silicon, phosphorous, or halogen. The heteroatom(s) may be present as a part of one or more heteroatom-containing functional groups. Non-limiting examples of heteroatom-containing functional groups include ether, hydroxy, epoxy, carbonyl, carboxamide, carboxylic ester, carboxylic acid, imine, imide, amine, sulfonic, sulfonamide, phosphonic, and silane groups. The heteroatom(s) may also be present as a part of a ring such as in heteroaryl and heteroarylene groups.

The term “halogen” or “halo” refers to Cl, Br, I, or F.

The term “ammonium” includes protonated NH₃ as well as protonated primary, secondary, and tertiary organic amines.

The term “functionalized” with reference to any moiety refers to the presence of one or more “functional groups” in the moiety. Various functional groups may be introduced in a moiety by way of one or more functionalization reactions known to a person having ordinary skill in the art. Non-limiting examples of functionalization reactions include: alkylation, epoxidation, sulfonation, hydrolysis, amidation, esterification, hydroxylation, dihydroxylation, amination, ammonolysis, acylation, nitration, oxidation, dehydration, elimination, hydration, dehydrogenation, hydrogenation, acetalization, halogenation, dehydrohalogenation, Michael addition, aldol condensation, Canizzaro reaction, Mannich reaction, Clasien condensation, Suzuki coupling, carboxylation, sulfonation, carboxylic acid salt formation, sulfonic acid salt formation, and the like. The term “unfunctionalized” with reference to any moiety refers to the absence of functional groups in the moiety.

The term “monomer” refers to a small molecule that chemically bonds during polymerization to one or more monomers of the same or different kind to form a polymer.

The term “polymer” refers to a large molecule comprising one or more types of monomer residues (repeating units) connected by covalent chemical bonds. By this definition, polymer encompasses compounds wherein the number of monomer units may range from very few, which more commonly may be called as oligomers, to very many. Non-limiting examples of polymers include homopolymers, and non-homopolymers such as copolymers, terpolymers, tetra-polymers and the higher analogues. The polymer may have a random, block, and/or alternating architecture. The polymers may be nonionic, or may be cationic, anionic, or amphoteric in nature.

The term “homopolymer” refers to a polymer that consists essentially of a single monomer type.

The term “non-homopolymer” refers to a polymer that comprises more than one monomer types.

The term “copolymer” refers to a non-homopolymer that comprises two different monomer types.

The term “terpolymer” refers to a non-homopolymer that comprises three different monomer types.

The term “branched” refers to any non-linear molecular structure. The term includes both branched and hyper-branched structures.

The term “radiation sensitive” refers to the condition of exhibiting an alteration in one or more intrinsic or extrinsic properties in response to an incident radiation.

The term “metal” refers to a material that, when freshly prepared, polished, or fractured, typically shows a lustrous appearance, and is a good conductor of electricity and heat. This definition of a metal includes the several scientifically accepted categories of metals such as alkali metals, alkaline earth metals, lanthanoids, actinoids, transition metals, and post-transition metals.

The term “alkali metal” refers to metal elements lithium, sodium, potassium, rubidium, cesium, and francium.

The term “alkaline earth metal” refers to metal elements beryllium, magnesium, calcium, strontium, barium, and radium.

The term “lanthanoid” refers to metal elements with atomic numbers 57 through 71 (inclusive) in the periodic table, from lanthanum through lutetium.

The term “actinoid” refers to metal elements with atomic numbers 89 through 103 (inclusive) in the periodic table, from actinium through lawrencium.

The term “transition metal” refers to a metal element whose atom has a partially filled d sub-shell, or which can give rise to cations with an incomplete d sub-shell. Particular, yet non-limiting examples of post-transition metals include scandium, titanium, vanadium, chromium, manganese, iron, cobalt, nickel, copper, zinc, rhodium, and palladium.

The term “post-transition metal” refers to a metal element that is typically soft, has poor mechanical strength, and/or has melting point lower than those of transition metal elements. Particular, yet non-limiting examples of post-transition metals include aluminum, gallium, indium, thallium, tin, lead, bismuth, and polonium.

The term “metalloid” refers to an element which demonstrates properties which are intermediate between the properties of typical metals and typical non-metals. For example, a metalloid may be an element which has the physical appearance and properties of a metal but behaves chemically as a non-metal. Particular, yet non-limiting examples of metalloids include silicon, boron, arsenic, germanium, antimony, and tellurium.

The term “amelioration agent” refers to an ingredient in a composition or formulation that provides a beneficial physical and/or chemical effect.

The term “coating composition” refers to a composition in the form of, for example, a solution, an emulsion, a suspension, or a dispersion, that is suitable for applying onto a surface of a substrate.

The term “substrate” refers to a material that serves as a base for a composition such as a coating composition.

The term “device” refers to a fabricated material.

All percentages, ratio, and proportions used herein are based on a weight basis unless other specified.

In a first aspect, the disclosed and/or claimed inventive concept(s) provides a radiation sensitive coating composition comprising a component (a) and a component (b) wherein the component (a) is a metal compound or a metalloid compound and the component (b) is at least one different metal compound or metalloid compound. In one non-limiting embodiment, the component (a) in the radiation sensitive coating composition is selected from the group consisting of bismuth compounds, cesium compounds, barium compounds, tungsten compounds, and combinations thereof. In one non-limiting embodiment, the component (b) in the radiation sensitive coating composition is selected from the group consisting of an aluminum compound, a lead compound, a silicon compound, and combinations thereof.

In one non-limiting embodiment, the radiation comprises ionizing radiation or electromagnetic radiation. In one non-limiting embodiment, the ionizing radiation comprises alpha rays, beta rays, or neutron rays. In one non-limiting embodiment, the electromagnetic radiation comprises visible radiation, ultraviolet radiation, infrared radiation, X-rays, or gamma rays.

In one non-limiting embodiment, the bismuth compound is selected from the group consisting of bismuth oxide, bismuth chloride oxide, bismuth sulfide, bismuth hydroxide, bismuth carbonate, bismuth silicate, bismuth subcarbonate, bismuth hydride, bismuth selenide, bismuth telluride, bismuth polonide, bismuth chalconides, bismuth fluoride, bismuth chloride, bismuth bromide, bismuth iodide, bismuth salts, bismuth complexes, bismuth alloys, bismuth vanadate, bismuth orthovanadate, bismuth vanadate molybdate, bismuth nitrate, bismuth manganese oxide, bismuth oxide iodide, bismuth oxide bromide, and combinations thereof. Non-limiting, yet particular examples of bismuth compounds can be found in the PCT application WO 2007/057327, the contents of which are herein incorporated by reference in its entirety.

In one non-limiting embodiment, the cesium compound is selected from the group consisting of cesium chloride, cesium bitartrate, cesium halide, cesium polyhalide, cesium polyiodide, cesium oxide, cesium sulfide, cesium polysulfide, cesium carbonate, and combinations thereof. Band et al. in J. Phys. Chem. B (2004), 108, 33, 12360-12367 synthesize cesium oxides and characterize them using a combination of chemical and structural analysis techniques. Ferguson and Gorrie in Cesium and Cesium Compounds, Kirk-Othmer Encyclopedia of Chemical Technology (2011) describe the methods of extraction, synthesis, properties, and applications of cesium compounds. The contents of these references are herein incorporated by reference in their entirety.

In one non-limiting embodiment, the barium compound is selected from the group consisting of barium sulfate, barium oxide, barium dithionate, and combinations thereof. Kresse et al. in Barium and Barium Compounds, Ullmann's Encyclopedia of Industrial Chemistry (2007) describe the history, production, analysis, and uses of barium and barium compounds, the contents of which are herein incorporated by reference in its entirety.

In one non-limiting embodiment, the tungsten compound is selected from the group consisting of tungsten carbide, tungsten oxide, and combinations thereof. Lassner et al. in book chapter: Tungsten Compounds and Their Application, Tungsten (1999) provide a summary of tungsten compounds with metallic as well as non-metallic elements, the contents of which are herein incorporated by reference in its entirety.

In one non-limiting embodiment, the aluminum compound is selected from the group consisting of aluminum oxide, aluminum hydride, aluminum sulfate, aluminum potassium sulfate, and combinations thereof.

In one non-limiting embodiment, the lead compound is selected from the group consisting of lead salts, lead sulfate, lead oxide, lead chloride, lead bromide, lead iodide, and combinations thereof.

In one non-limiting embodiment, the silicon compound is selected from the group consisting of silicon dioxide, silica, fumed silica, silica gel, aerogel, precipitated silica, and combinations thereof.

In one non-limiting embodiment, the component (a) in the radiation sensitive coating composition is a compound selected from the group consisting of a bismuth compound, a cesium compound, a barium compound, a tungsten compound, and combinations thereof, and the component (b) in the radiation sensitive coating composition is a compound selected from the group consisting of an aluminum compound, a lead compound, a silicon compound, and combinations thereof.

In one non-limiting embodiment, the component (a) in the radiation sensitive coating composition is a bismuth compound and the component (b) in the radiation sensitive coating composition is a compound selected from the group consisting of an aluminum compound, a lead compound, a silicon compound, and combinations thereof.

In one non-limiting embodiment, the component (a) in the radiation sensitive coating composition is a bismuth compound and the component (b) in the radiation sensitive coating composition is an aluminum compound.

In one non-limiting embodiment, the component (a) in the radiation sensitive coating composition is a bismuth compound selected from the group consisting of bismuth oxide, bismuth chloride oxide, bismuth sulfide, bismuth hydroxide, bismuth carbonate, bismuth silicate, bismuth subcarbonate, bismuth hydride, bismuth selenide, bismuth telluride, bismuth polonide, bismuth chalconides, bismuth fluoride, bismuth chloride, bismuth bromide, bismuth iodide, bismuth salts, bismuth complexes, bismuth alloys, bismuth vanadate, bismuth orthovanadate, bismuth vanadate molybdate, bismuth nitrate, bismuth manganese oxide, bismuth oxide iodide, bismuth oxide bromide, and combinations thereof, and the component (b) in the radiation sensitive coating composition is an aluminum compound is selected from the group consisting of aluminum oxide, aluminum sulfate, aluminum potassium sulfate, and combinations thereof.

In one non-limiting embodiment, the component (a) in the radiation sensitive coating composition is bismuth oxide and the component (b) in the radiation sensitive coating composition is aluminum oxide.

In a second aspect, the disclosed and/or claimed inventive concept(s) provides a radiation sensitive composition comprising a component (a), a component (b), and a component (c) wherein the component (a) is a metal compound or a metalloid compound, the component (b) is at least one different metal compound or metalloid compound, and the component (c) is at least one functionalized or unfunctionalized acetylenic compound.

In one non-limiting embodiment, the component (a) in the radiation sensitive composition is a compound selected from the group consisting of a bismuth compound, a cesium compound, a barium compound, a tungsten compound, and combinations thereof, the component (b) in the radiation sensitive composition is a compound selected from the group consisting of an aluminum compound, a lead compound, a silicon compound, and combinations thereof, and the component (c) in the radiation sensitive composition is at least one functionalized or unfunctionalized acetylenic compound.

In one non-limiting embodiment, the component (a) in the radiation sensitive composition is a bismuth compound, the component (b) in the radiation sensitive composition is a compound selected from the group consisting of an aluminum compound, a lead compound, a silicon compound, and combinations thereof, and the component (c) in the radiation sensitive composition is at least one functionalized or unfunctionalized acetylenic compound.

In one non-limiting embodiment, the component (a) in the radiation sensitive composition is a bismuth compound, the component (b) in the radiation sensitive composition is an aluminum compound, and the component (c) in the radiation sensitive composition is at least one functionalized or unfunctionalized acetylenic compound.

In one non-limiting embodiment, the component (a) in the radiation sensitive composition is a bismuth compound selected from the group consisting of bismuth oxide, bismuth chloride oxide, bismuth sulfide, bismuth hydroxide, bismuth carbonate, bismuth silicate, bismuth subcarbonate, bismuth hydride, bismuth selenide, bismuth telluride, bismuth polonide, bismuth chalconides, bismuth fluoride, bismuth chloride, bismuth bromide, bismuth iodide, bismuth salts, bismuth complexes, bismuth alloys, bismuth vanadate, bismuth orthovanadate, bismuth vanadate molybdate, bismuth nitrate, bismuth manganese oxide, bismuth oxide iodide, bismuth oxide bromide, and combinations thereof, the component (b) in the radiation sensitive composition is an aluminum compound is selected from the group consisting of aluminum oxide, aluminum sulfate, aluminum potassium sulfate, and combinations thereof, and the component (c) in the radiation sensitive composition is at least one functionalized or unfunctionalized acetylenic compound.

In one non-limiting embodiment, the component (c) is a functionalized acetylenic compound comprising an acetylene moiety and at least one non-acetylenic functional group. In another non-limiting embodiment, the component (c) is a functionalized acetylenic compound comprising at least two acetylene moieties and at least one non-acetylenic functional group.

In one non-limiting embodiment, the non-acetylenic functional group is selected from the group consisting of carboxyl, carboxylate, hydroxy, hydroxide, alkoxy, alkoxide, epoxy, amino, ammonium, aldehyde, keto, amide, ester, nitrile, urethane, ether, and combinations thereof. In one non-limiting embodiment, the non-acetylenic functional group is selected from the group consisting of carboxyl, carboxylate, and combinations thereof.

In one non-limiting embodiment, the component (c) is a functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof.

In one non-limiting embodiment, the component (c) is 10,12-pentacosadiynoic acid or a salt thereof.

In one non-limiting embodiment, the component (a) in the radiation sensitive coating composition is a compound selected from the group consisting of a bismuth compound, a cesium compound, a barium compound, a tungsten compound, and combinations thereof, the component (b) in the radiation sensitive coating composition is a compound selected from the group consisting of an aluminum compound, a lead compound, a silicon compound, and combinations thereof, and the component (c) in the radiation sensitive coating composition is at least one functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof.

In one non-limiting embodiment, the component (a) in the radiation sensitive coating composition is a bismuth compound, the component (b) in the radiation sensitive coating composition is a compound selected from the group consisting of an aluminum compound, a lead compound, a silicon compound, and combinations thereof, and the component (c) in the radiation sensitive coating composition is at least one functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof.

In one non-limiting embodiment, the component (a) in the radiation sensitive coating composition is a bismuth compound, the component (b) in the radiation sensitive coating composition is an aluminum compound, and the component (c) in the radiation sensitive coating composition is at least one functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof.

In one non-limiting embodiment, the component (a) in the radiation sensitive coating composition is bismuth oxide, the component (b) in the radiation sensitive coating composition is aluminum oxide, and the component (c) in the radiation sensitive coating composition is selected from the group consisting of 10,12-pentacosadiynoic acid, a salt thereof, and combinations thereof.

In one non-limiting embodiment, the salt as disclosed herein is obtained by the reaction of the functionalized or unfunctionalized acetylenic compound and a substance selected from the group consisting of organic acids, organic bases, inorganic acids, inorganic bases, complex formers, crystal formers, cocrystal formers, and combinations thereof. In one non-limiting embodiment, the substance is selected from the group consisting of functionalized or unfunctionalized aliphatic amines, alicyclic amines, heterocyclic amines, aromatic amines, heteroaromatic amines, and combinations thereof. In another non-limiting embodiment, the substance is selected from the group consisting of functionalized or unfunctionalized alkyl amines, dialkyl amines, trialkyl amines, quaternary amines, pyridines, azopyridines, bipyridyls, pyrimidines, pyrazines, piperidines, bipiperidines, morpholines, and combinations thereof. In yet another non-limiting embodiment, the substance is selected from the group consisting of metals and inorganic bases. In yet another non-limiting embodiment, the substance is selected from the group consisting of hydrides, oxides, hydroxides, cyanides, carbonates, and bicarbonates of alkali and alkaline earth metal elements, and combinations thereof.

Non-limiting, yet particular examples of organic bases include 4,4′-azopyridine, 4,4′-bipyridyl, trans-1,2-bis(4-pyridyl)ethylene, 4,4′-bipiperidine, morpholine, diethylamine, n-butylamine, and combinations thereof. Other suitable examples of organic bases can be found in ULLMANN's Encyclopedia of Industrial Chemistry, 7^{th} Edition, 2002, Wiley-VCH Verlag GmbH & Co. KGaA, the contents of which are herein incorporated by reference in its entirety.

Non-limiting, yet particular examples of inorganic bases can be found in ULLMANN's Encyclopedia of Industrial Chemistry, 7^{th} Edition, 2002, Wiley-VCH Verlag GmbH & Co. KGaA, the contents of which are herein incorporated by reference in its entirety.

Additional insight into the properties, functionality and application(s) of radiation sensitive acetylene compounds is disclosed in Hall et al. in Chemical Science, 2020, volume 11, 8025-8035, the disclosure of which is herein incorporated by reference in its entirety.

In a third aspect, the disclosed and/or claimed inventive concept(s) provides a radiation sensitive composition comprising a component (a), a component (b), a component (c), and a component (d) wherein the component (a) is a metal compound or a metalloid compound, the component (b) is at least one different metal compound or metalloid compound, the component (c) is at least one functionalized or unfunctionalized acetylenic compound, and the component (d) is at least one amelioration agent.

In one non-limiting embodiment, the component (a) in the radiation sensitive coating composition is a compound selected from the group consisting of a bismuth compound, a cesium compound, a barium compound, a tungsten compound, and combinations thereof, the component (b) in the radiation sensitive coating composition is a compound selected from the group consisting of an aluminum compound, a lead compound, a silicon compound, and combinations thereof, the component (c) in the radiation sensitive coating composition is at least one functionalized or unfunctionalized acetylenic compound, and the component (d) in the radiation sensitive coating composition is at least one amelioration agent.

In one non-limiting embodiment, the component (a) in the radiation sensitive coating composition is a bismuth compound, the component (b) in the radiation sensitive coating composition is a compound selected from the group consisting of an aluminum compound, a lead compound, a silicon compound, and combinations thereof, the component (c) in the radiation sensitive coating composition is at least one functionalized or unfunctionalized acetylenic compound, and the component (d) in the radiation sensitive coating composition is at least one amelioration agent.

In one non-limiting embodiment, the component (a) in the radiation sensitive coating composition is a bismuth compound, the component (b) in the radiation sensitive coating composition is an aluminum compound, the component (c) in the radiation sensitive coating composition is at least one functionalized or unfunctionalized acetylenic compound, and the component (d) in the radiation sensitive coating composition is at least one amelioration agent.

In one non-limiting embodiment, the component (a) in the radiation sensitive coating composition is a compound selected from the group consisting of a bismuth compound, a cesium compound, a barium compound, a tungsten compound, and combinations thereof, the component (b) in the radiation sensitive coating composition is a compound selected from the group consisting of an aluminum compound, a lead compound, a silicon compound, and combinations thereof, the component (c) in the radiation sensitive coating composition is at least one functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof, and the component (d) in the radiation sensitive coating composition is at least one amelioration agent.

In one non-limiting embodiment, the component (a) in the radiation sensitive coating composition is a bismuth compound, the component (b) in the radiation sensitive coating composition is a compound selected from the group consisting of an aluminum compound, a lead compound, a silicon compound, and combinations thereof, the component (c) in the radiation sensitive coating composition is at least one functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof, and the component (d) in the radiation sensitive coating composition is at least one amelioration agent.

In one non-limiting embodiment, the component (a) in the radiation sensitive coating composition is a bismuth compound, the component (b) in the radiation sensitive coating composition is an aluminum compound, the component (c) in the radiation sensitive coating composition is at least one functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof, and the component (d) in the radiation sensitive coating composition is at least one amelioration agent.

In one non-limiting embodiment, the component (a) in the radiation sensitive coating composition is bismuth oxide, the component (b) in the radiation sensitive coating composition is aluminum oxide, the component (c) in the radiation sensitive coating composition is selected from the group consisting of 10,12-pentacosadiynoic acid, a salt thereof, and combinations thereof, and the component (d) in the radiation sensitive coating composition is at least one amelioration agent.

In one non-limiting embodiment, the amelioration agent is selected from the group consisting of adsorption agents, binders, dyes, polymers, shelf-life extenders, solvents, stabilizers, surfactants, and combinations thereof.

Non-limiting, yet particular examples of binders include homopolymers, copolymers, graft-copolymers, block copolymers, polymeric alloys, and mixtures thereof. A large number of monomers and oligomers can be used to make these polymeric binders. Non-limiting, yet particular examples of such monomers include unsaturated monomers such as olefins, vinyls, acrylates, and (meth) acrylates such as methyl methacrylate, methyl acrylate, styrene, acrylic acid, butane diol 1,4-dimethacrylate, diethylene glycol diacrylate, diethylene glycol dimethacrylate, ethylene glycol dimethacrylate, hexanediol-1,6-dimethacrylate, methylstyrene pentaerylthriol triacrylate, polyethylene glycol dimethacrylate, polypropylene glycol dimethacrylate, triethylene glycol dimethacrylate, 4-(vinyloxy) butyl benzoate, bis[4-(vinyloxy)butyl] adipate, bis[4-(vinyloxy)butyl] succinate, 4-(vinyloxymethyl)cyclohexylmethyl, bis[4-(vinyloxy)butyl] isophthalate, bis[4-(vinyloxymethyl)cyclohexylmethyl], tris[4-(vinyloxy)butyl] trimellitate, 4-(vinyloxy)butyl stearate, bis[4-(vinyloxy)butyl] hexanediylbiscarbamate, bis[[4-[(vinyloxy)methyl]cyclohexyl]methyl], bis[[4-[(vinyloxy)methyl]cyclohexy]methyl], bis[4-(vinyloxy)butyl] (4-methyl-1,3-phenylene), and combinations thereof.

Further non-limiting, yet particular examples of binders include latex emulsion polymers. For a latex emulsion polymer, components include polymers which are the reaction products of one or more ethylenically unsaturated monomers. Non-limiting, yet particular examples of useful ethylenically unsaturated monomers include acrylic acid, acrylonitrile, acetoacetoxy ethyl methacrylate, acetoacetoxy ethyl acrylate, butyl acrylate, butadiene, butyl methacrylate, butyl acrylamide, chloromethyl styrene, crotonic acid, ethyl acrylate, ethyl acrylamide, ethylene, ethyl methacrylate, ethylhexyl acrylate, 2-ethylhexyl acrylate, 2-ethylhexyl methacrylate, glycidyl methacrylate, hydroxyethyl (meth)acrylate, hydroxypropyl (meth)acrylate, isobutyl acrylate, isobutyl methacrylate, isoprene, iso-octyl acrylate, iso-octyl methacrylate itaconic acid, methyl acrylate, octyl acrylate, octyl methacrylate, methyl methacrylate, methacrylic acid, α-methyl styrene, styrene, vinyl chloride vinyl naphthalene, vinyl toluene, vinylidene chloride, vinyl acetate, and the like.

Alkyd resins are generally comprised of polybasic acids, polyhydric alcohols, and fatty acids which may be unsaturated. The polybasic acids such as aromatic, aliphatic and alicyclic saturated and unsaturated compounds, such as adipic acid, chlorendic acid, heptanedioic acid, isophthalic acid, maleic acid, napthalic acid, phthalic acid, sebacic acid, succinic acid, trimellitic acid, terephthalic acid, and tetrahydrophthalic acid. Polyhydric alcohol components include 1,3-butylene glycol, diethylene glycol, dipentaerythritol, dipropylene glycol, ethylene glycol, glycerin, 1,6-hexanediol, neopentyl glycol, pentaerythritol, propylene glycol, sorbitol, trimethylol ethane, trimethylol propane and triethylene glycol. Fatty acids used in the manufacture of alkyds commonly include dehydrated castor oil, coconut oil, cottonseed oil, fish oil, linseed oil, oiticica oil, tung oil, safflower oil, soya oil and tall oil acids.

Polyurethane resins are formed from polyisocyanate (aliphatic, aromatic, or combinations thereof) compounds. Examples of aliphatic isocyanates include butane diisocyanate, 4,4′-diisocyanatodicyclohexylmethane, hexamethylene diisocyanate, hexahydroxylylene diisocyanate, isophorone diisocyanate, 1-methyl-2,4(2,6)-diisocyanato cyclohexane, norbornane diisocyanate, and tetramethylxylylene diisocyanate. Examples of aliphatic and aromatic isocyanates include 4,4′-biphenylene diisocyanate, 4-chloro-1,3-phenylene diisocyanate, 1,4-cyclohexylene diisocyanate, 1,10-deca-ethylene diisocyanate, methylene bis-(4-phenyl isocyanate), 4,4-methylene-bis(cyclohexyl isocyanate), 1,5-naphthalene diisocyanate, 1,3-phenylene diisocyanate, 2,4-tolylene diisocyanate, 2,6-tolylene diisocyanate, 1,4-tetramethylene diisocyanate and 1,5-tetrahydronaphthalene diisocyanate.

In addition to isocyanates, alcohols and carboxylic acids, which form polyester compositions, can also be used in the preparation of polyurethane resins. The polycarboxylic acids may be of an aliphatic, cycloaliphatic, aromatic and/or heterocyclic nature and may comprise halogen atoms and/or unsaturated moieties. Suitable acids include adipic acid, azeleic acid, bis-glycol terephthalate, dimeric fatty acids, dimethyl terephthalate, endomethylenetetrahydrophthalic anhydride, fumaric acid, glutaric anhydride, hexahydrophthalic anhydride, isophthalic acid, maleic acid, maleic anhydride, phthalic anhydride, phthalic acid, suberic acid, succinic acid, sebacic acid, tetrahydrophthalic anhydride and tetrachlorophthalic anhydride. Polyhydric alcohols examples include 1,4-, 1,3- and 2,3-butylene glycol, cyclohexanedimethanol (1,4-bis-hydroxymethylcyclohexane), diethylene glycol, dipropylene glycol, dibutylene glycol, ethylene glycol, 1,2- and 1,3-propylene glycol, 1,6-hexanediol, 2-methyl-1,3-propanediol, neopentylglycol, 1,8-octanediol, polyethylene glycol, polypropylene glycol, polybutylene glycol, triethylene glycol and tetraethylene glycol. Polyesters comprising carboxyl groups and terminal carboxyl groups are envisioned. Diols comprising carboxyl or carboxylate groups which are suitable to support ionic or potentially ionic groups are envisioned. Such moieties can be constructed by dihydroxysuccinic acid, dimethylolacetic acid, 2,2-dimethylolpropionic acid, 2,2-dimethylolbutyric acid and 2,2-dimethylolpentanoic acid. Polyesters constructed from lactones are also envisioned. Polycarbonates comprising hydroxyl groups are useful and are prepared by reacting diols with dicarbonates such as diphenyl carbonate or phosgene. Polyethers comprising diols, formed from polymers derived from ethylene oxide, propylene oxide and/or tetrahydrofuran are also useful. An amine functionality can be employed to introduce terminal hydroxyl functionality, with compounds such as diethanolamine, ethanolamine, N-methylethanolamine, propanolamine, N,N,N′-tris-2-hydroxyethyl-ethylendiamine.

Epoxy resins are comprised primarily of linear chain molecules. These molecules are formed from the reaction of bisphenols with halohydrins to yield epoxy resins containing epoxy groups. Common bisphenols include bisphenol-A, bisphenol-F, bisphenol-S, and 4,4′ dihydroxy bisphenol. Common halohydrins include epichlorohydrin, dichlorohydrin, and 1,2-dichloro-3-hydroxypropane.

Non-limiting, yet particular examples of commercially available epoxy resins include Dow Chemical epoxy resins DER 333, DER 661 and Shell Chemical epoxy resins EPON 828, EPON 836, and EPON 1001. Ciba-Geigy epoxy resins GT-7013, GT-7014, GT-7074, GT-259 and Air Products Ancarez® AR 555.

Non-limiting, yet particular examples of commercial latex emulsion polymers, available from Air Products, BASF, Bayer, Celanese, Chemtura, Dow, Hexion, Styron and Wacker, include Ancarez®, Acclaim®, Acronal 296D, Aquamac 705, Aquamac 588, Arcol®, Avanse™, Avicor®, Baybond®, Bayhydrol®, Bayhydur®, Britecoat®, Celvaset®, Desmodur®, Dur-o-coat®, Dur-o-set®, Ecovae®, EVEREST™ Latex Technology, ENVERSA™, Flexbond®, Formashield™, FOUNDATIONS™ Latex, Hiloft®, HPL™ Latex, LOMAX™ Latex, Nacrylic®, Resyn®, Rhoplex SG-30, Rhoplex HG-74P, Rhoplex SG-10M, Rhoplex AC_{2508,} Trumoda®, Tufcor®, UCAR 313, UCAR 626, UCAR 379G, Vinac®, Vinamul®, Vinnapas®, Witcobond®, X-Link® and the like. Combinations of latex emulsions are also envisioned. Latex can also be functionalized and further cross-linked as required.

Non-limiting, yet particular examples of rheology modifiers include cellulosics, modified ureas, polyurethane thickeners and associative thickeners, alkali swellable emulsions (ASE), hydrophobically modified alkali swellable emulsions (HASE), hydrophobically modified polyurethanes (HEURS), hydrophobically modified polyethers (HMPE), attapulgites, acrylate thickeners, amides and organic derivatives, fumed silicas, synthetic layered silicates, organoclays, mixed minerals, thixotropy boosters, polyalkylene ether derivatives, starches, polyacrylates, surfactants, and hydrophobically modified polymers and copolymers.

Non-limiting, yet particular examples of functional binders, including rheological modification, are polyvinyl pyrrolidone, poly(vinyl pyrrolidone-co-vinyl acetate), polyvinylcaprolactam, poly(vinyl pyrrolidone-co-vinyl caprolactam), poly(vinyl pyrrolidone-co-dimethylaminopropylmethacrylamide, poly(vinyl pyrrolidone-co-vinyl caprolactam-co-dimethylaminopropylmethacrylamide), poly(isobutylene-co-ethylmaleimide-co-hydroxyethylmaleimide), poly(vinyl pyrrolidone-co-dimethylaminoethylmethacrylate), quaternized poly(vinyl pyrrolidone-co-dimethylaminoethylmethacrylate), poly(vinyl pyrrolidone-co-vinyl caprolactam-co-dimethylaminoethylmethacrylate), poly(vinyl acetate-co-crotonates-co-vinylneodecanoate), poly(2-ethyl oxazoline), polyethylene imine, poly(2-alkyl oxazoline), poly(octylacrylamide-co-acrylate-co-butylamino ethylmethacrylate), polyvinyl alcohol, partially hydrolyzed polyvinyl alcohol, acetoacetylated polyvinyl alcohol, polyalkylene imines, polydi allyldialkylammonium chloride, starches, modified starches, polyurethanes, acrylated oligomers of polyurethanes, acrylated glycidyl oligomers, polyfunctional acrylates, cellulosics, silane or silicone based polymers, anionic polyacrylates such as polyacrylic acid, poly(maleic anhydride-alt-methyl vinyl ether), poly(methylvinylether-alt-maleic acid), poly(methylvinylether-alt-maleic acid) ester, poly(methylvinylether-alt-maleic anhydride) ester copolymer, poly(styrene-co-maleic acid), poly(styrene-co-maleic acid) ester, poly(styrene-co-maleic anhydride), poly(styrene-co-maleic anhydride) ester, styrene acrylic acid copolymer, styrene acrylic acid ester copolymer, hydrophobically modified polyacetal polyether, maleimide/maleic acid copolymer, urethane acrylate methacrylate, acrylic polymer, polyoxyethylene-polyoxypropylene block copolymer, and hydrophobically modified ethoxylated urethane. Cellulose and derivatives include ethyl cellulose (EC), hydroxyethyl cellulose (HEC), hydroxypropyl cellulose (HPC), ethylhydroxyethyl cellulose (EHEC), carboxymethyl cellulose (CMC), carboxymethylhydroxyethyl cellulose (CMHEC), hydroxypropylhydroxyethyl cellulose (HMHEC), methylcellulose (MC), methylhydroxypropyl cellulose (MHPC), methylhydroxyethyl cellulose (MHEC), carboxymethylmethylcellulose (CMMC), hydrophobically modified carboxymethylcellulose (HMCMC), hydrophobically modified hydroxyethyl cellulose (HMHEC), hydrophobically modified hydroxylpropyl cellulose (HMHPC), hydrophobically modified ethylhydroxyethyl cellulose (HMEHEC), hydrophobically modified carboxymethylhydroxyethyl cellulose (HMCMHEC), hydrophobically modified hydroxypropylhydroxyethyl cellulose (HMHPHEC), hydrophobically modified methyl cellulose (HMMC), hydrophobically modified methylhydroxypropyl cellulose (HMMHPC), hydrophobically modified methylhydroxyethyl cellulose (HMMHEC), hydrophobically modified carboxymethylmothyl cellulose (HMCMMC), cationic hydroxyethyl cellulose (cationic HEC), cationic hydrophobically modified hydroxyethyl cellulose (cationic HMHEC), nano fibrillated cellulosics (NFC), and microfibrillated cellulosics (MFC). Guar and guar derivatives include carboxymethyl guar, carboxymethylhydroxypropyl guar, cationic hydroxypropyl guar, hydroxyalkyl guar, including hydroxyethyl guar, hydroxypropyl guar, hydroxybutyl guar and higher hydroxylalkyl guars, carboxylalkyl guars, including carboxymethyl guar, carboxylpropyl guar, carboxybutyl guar, and higher alkyl carboxy guars, the hydroxyethylated, hydroxypropylated and carboxymethylated derivative of guaran, the hydroxethylated and carboxymethylated derivatives of Carubin and the hydroxypropylated and carboxymethylated derivatives of Cassia-Gum.

Non-limiting, yet particular examples of solvents include water, high boiling solvents such as butoxy-2-ethylstearate, butyrolactone, diethyl fumarate, dimethyl maleate, dimethylcarbonate, dioctyl phthalate, ethylene glycol dimethyl ether ethyl salicylate, polyethylene glycol dimethylether, propylene carbonate, triacetin, benzyl ether, dodecyl-1,2-methyl pyrrolidone, ethoxyethylacetate, glycol ethylene diacetate, ethyltrichloroacetate, methylpyrrolidone, methyl sulfoxide, polyethylene glycols of different molecular weight, dimethylformamide, cyclohexane, p-dioxane, tetrahydrofuran, and p-xylene.

Non-limiting, yet particular examples of dyes include new Sunset Yellow, fuschin cyanide, hexahydroxy ethyl violet cyanide, pararose aniline cyanide, leuco crystal violet, leuco malachite green, carbinol dyes such as malachite green base and p-roseaniline base, and those described in U.S. Pat. Nos. 2,877,169; 3,079,955; and 4,377,751, each of which disclosure is herein incorporated by reference in its entirety. Other examples of dyes can be found in the patent EP1529089 B1 that is herein incorporated by reference in its entirety.

Non-limiting, yet particular examples of activators include a halocarbon, a halonium, a sulfonium, ethyl trichloroacetate, heptachloropropane, ethyltrichloroacetate, chloroacetic acid, chloropropionic acid, hexachlorocyclohexane, methyltrichloroacetimidate, trichloroacetic acid, trichloroacetamide, trichloro ethanol, trichloro methyl benzyl acetate, trichloro methyl propanol hydrate, trichloro propane, chlorinated polymers, diphenyliodinium iodide, diphenyliodinium hexafluoroarsenate, diphenyliodinium chloride, trimethylsulfonium iodide and triphenylsulfonium hexafluoroantimonate.

In one non-limiting embodiment, the amelioration agent is selected from the group consisting of cyclic oximes. Non-limiting, yet particular examples of cyclic oximes include saturated ring-containing oximes such as cyclopentanone oximes, cyclohexanone oximes, cycloheptanone oximes, 2-methyl cyclohexanone oximes, 3-methylcyclohexanone oximes, 4-methylcyclohexanone oximes, and combinations thereof.

In one non-limiting embodiment, the amelioration agent is a shelf life extender. In one non-limiting embodiment, the shelf-life extender is selected from the group consisting of heat stabilizers, reactive species quenchers, free radical scavengers, oxygen scavengers, antioxidants, reaction inhibitors of the selected reactive species, thermo-oxidation inhibitors, photo-oxidation inhibitors, hydroperoxide decomposers, H-donors, UV stabilizers, UV absorbers, UV reflectors, and fluorescent optical brighteners.

In one non-limiting embodiment, one or more polymers as amelioration agents is selected from the group consisting of polybutylene, polymethyl(meth)acrylate, polybutyl(meth)acrylate, polybutyl(meth)acrylate-co-isobutyl(meth)acrylate, polyethylene, poly(ethylene-co-acrylic acid), polyethyl(meth)acrylate), polyethylene-co-vinylacetate, polyisobutyl(meth)acrylate, polyvinyl alcohol, polyvinyl butyral, polyvinyl chloride, polyvinyl stearate, poly(ethylene-co-(meth)acrylic acid), polybutadiene, polyvinyl acetate, poly(ethyelene-co-butylacrylate-co-carbon monoxide), poly(o-cresyl glycidyl ether)-formaldehyde, poly(ethyelene-co-1-butene), poly(ethyelene-co-(meth)acrylate), polyhexamethyleneadipate, polyhexamethylenevinylene, other functional polymers and combinations thereof.

Other examples of amelioration agents can be found in the patent U.S. Pat. No. 7,476,874 that is herein incorporated by reference in its entirety. General methods of preparation of radiation sensitive compositions can be found in U.S. Pat. No. 7,445,880 that is herein incorporated by reference in its entirety.

In a fourth aspect, the disclosed and/or claimed inventive concept(s) provides a substrate coated with a radiation sensitive composition comprising a component (a), a component (b), a component (c), and a component (d) wherein the component (a) is a metal compound or a metalloid compound, the component (b) is at least one different metal compound or metalloid compound, the component (c) is at least one functionalized or unfunctionalized acetylenic compound, and the component (d) is at least one amelioration agent.

In one non-limiting embodiment, the component (a) in the radiation sensitive composition that is coated on the substrate is selected from the group consisting of bismuth compounds, cesium compounds, barium compounds, tungsten compounds, and combinations thereof.

In one non-limiting embodiment, the component (b) in the radiation sensitive composition that is coated on the substrate is selected from the group consisting of an aluminum compound, a lead compound, a silicon compound, and combinations thereof.

In one non-limiting embodiment, the bismuth compound in the component (a) in the radiation sensitive composition that is coated on the substrate is selected from the group consisting of bismuth oxide, bismuth chloride oxide, bismuth sulfide, bismuth hydroxide, bismuth carbonate, bismuth silicate, bismuth subcarbonate, bismuth selenide, bismuth telluride, bismuth chalconides, bismuth fluoride, bismuth chloride, bismuth bromide, bismuth iodide, bismuth salts, bismuth complexes, bismuth alloys, bismuth vanadate, bismuth orthovanadate, bismuth vanadate molybdate, bismuth nitrate, bismuth manganese oxide, bismuth oxide iodide, bismuth oxide bromide, and combinations thereof.

In one non-limiting embodiment, the cesium compound in the component (a) in the radiation sensitive composition that is coated on the substrate is selected from the group consisting of cesium chloride, cesium bitartrate, cesium halide, cesium polyhalide, cesium polyiodide, cesium oxide, cesium sulfide, cesium polysulfide, cesium carbonate, and combinations thereof.

In one non-limiting embodiment, the barium compound in the component (a) in the radiation sensitive composition that is coated on the substrate is selected from the group consisting of barium sulfate, barium oxide, barium dithionate, and combinations thereof.

In one non-limiting embodiment, the tungsten compound in the component (a) in the radiation sensitive composition that is coated on the substrate is selected from the group consisting of tungsten carbide, tungsten oxide, and combinations thereof.

In one non-limiting embodiment, the aluminum compound in the component (b) in the radiation sensitive composition that is coated on the substrate is selected from the group consisting of aluminum oxide, aluminum sulfate, aluminum potassium sulfate, and combinations thereof.

In one non-limiting embodiment, the lead compound in the component (b) in the radiation sensitive composition that is coated on the substrate is selected from the group consisting of lead salts, lead sulfate, lead chloride, lead bromide, lead oxide, lead iodide, and combinations thereof.

In one non-limiting embodiment, the silicon compound in the component (b) in the radiation sensitive composition that is coated on the substrate is selected from the group consisting of silicon dioxide, silica, fumed silica, silica gel, aerogel, precipitated silica, and combinations thereof.

In one non-limiting embodiment, the component (a) in the radiation sensitive composition that is coated on the substrate is a compound selected from the group consisting of a bismuth compound, a cesium compound, a barium compound, a tungsten compound, and combinations thereof, the component (b) in the radiation sensitive coating composition that is coated on the substrate is a compound selected from the group consisting of an aluminum compound, a lead compound, a silicon compound, and combinations thereof, the component (c) in the radiation sensitive composition that is coated on the substrate is at least one functionalized or unfunctionalized acetylenic compound, and the component (d) in the radiation sensitive composition that is coated on the substrate is at least one amelioration agent.

In one non-limiting embodiment, the component (a) in the radiation sensitive composition that is coated on the substrate is a bismuth compound, the component (b) in the radiation sensitive coating composition that is coated on the substrate is a compound selected from the group consisting of an aluminum compound, a lead compound, a silicon compound, and combinations thereof, the component (c) in the radiation sensitive composition that is coated on the substrate is at least one functionalized or unfunctionalized acetylenic compound, and the component (d) in the radiation sensitive composition that is coated on the substrate is at least one amelioration agent.

In one non-limiting embodiment, the component (a) in the radiation sensitive composition that is coated on the substrate is a bismuth compound, the component (b) in the radiation sensitive coating composition that is coated on the substrate is an aluminum compound, the component (c) in the radiation sensitive composition that is coated on the substrate is at least one functionalized or unfunctionalized acetylenic compound, and the component (d) in the radiation sensitive composition that is coated on the substrate is at least one amelioration agent.

In one non-limiting embodiment, the silicon compound in the component (c) in the radiation sensitive composition that is coated on the substrate is a functionalized acetylenic compound comprising an acetylene moiety and at least one non-acetylenic functional group. In one non-limiting embodiment, the non-acetylenic functional group is selected from the group consisting of carboxyl, carboxylate, hydroxy, hydroxide, alkoxy, alkoxide, epoxy, amino, ammonium, aldehyde, keto, amide, ester, nitrile, urethane, ether, and combinations thereof. In one non-limiting embodiment, the non-acetylenic functional group is selected from the group consisting of carboxyl, carboxylate, and combinations thereof.

In one non-limiting embodiment, the silicon compound in the component (c) in the radiation sensitive composition that is coated on the substrate is a functionalized acetylenic compound comprising at least two acetylene moiety and at least one non-acetylenic functional group. In one non-limiting embodiment, the non-acetylenic functional group is selected from the group consisting of carboxyl, carboxylate, hydroxy, hydroxide, alkoxy, alkoxide, epoxy, amino, ammonium, aldehyde, keto, amide, ester, nitrile, urethane, ether, and combinations thereof. In one non-limiting embodiment, the non-acetylenic functional group is selected from the group consisting of carboxyl, carboxylate, and combinations thereof.

In one non-limiting embodiment, the silicon compound in the component (c) in the radiation sensitive composition that is coated on the substrate is a functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof.

In one non-limiting embodiment, the acetylenic compound in the component (c) in the radiation sensitive composition that is coated on the substrate is 10,12-pentacosadiynoic acid or a salt thereof.

In one non-limiting embodiment, the component (a) in the radiation sensitive composition that is coated on the substrate is a compound selected from the group consisting of a bismuth compound, a cesium compound, a barium compound, a tungsten compound, and combinations thereof, the component (b) in the radiation sensitive coating composition that is coated on the substrate is a compound selected from the group consisting of an aluminum compound, a lead compound, a silicon compound, and combinations thereof, the component (c) in the radiation sensitive composition that is coated on the substrate is at least functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof, and the component (d) in the radiation sensitive composition that is coated on the substrate is at least one amelioration agent.

In one non-limiting embodiment, the component (a) in the radiation sensitive composition that is coated on the substrate is a bismuth compound, the component (b) in the radiation sensitive coating composition that is coated on the substrate is a compound selected from the group consisting of an aluminum compound, a lead compound, a silicon compound, and combinations thereof, the component (c) in the radiation sensitive composition that is coated on the substrate is at least one functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof, and the component (d) in the radiation sensitive composition that is coated on the substrate is at least one amelioration agent.

In one non-limiting embodiment, the component (a) in the radiation sensitive composition that is coated on the substrate is a bismuth compound, the component (b) in the radiation sensitive coating composition that is coated on the substrate is an aluminum compound, the component (c) in the radiation sensitive composition that is coated on the substrate is at least one functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof, and the component (d) in the radiation sensitive composition that is coated on the substrate is at least one amelioration agent.

In one non-limiting embodiment, the component (a) in the radiation sensitive composition that is coated on the substrate is bismuth oxide, the component (b) in the radiation sensitive coating composition that is coated on the substrate is aluminum oxide, the component (c) in the radiation sensitive composition that is coated on the substrate is selected from the group consisting of 10,12-pentacosadiynoic acid, a salt thereof, and combinations thereof, and the component (d) in the radiation sensitive composition that is coated on the substrate is at least one amelioration agent.

In one non-limiting embodiment, the substrate is selected from the group consisting of paper, polymer, plastic, textile, metal, canvas, cloth, wood, leather, ceramic, glass, and combinations thereof.

In one non-limiting embodiment, the paper is selected from the group consisting of plain paper, coated paper, treated paper, photographic quality paper, and combinations thereof.

In one non-limiting embodiment, the plastic is selected from the group consisting of vinyls, polyurethanes, polycarbonates, polyethers, polyesters, polyvinyl chloride, polystyrene, polyethylene, polyolefins, polyvinyl acetate, silicone rubbers, rubbers, polyester-polyether copolymers, ethylene methacrylate, silicones, nylon, polyamides, and combinations thereof.

In a fifth aspect, the disclosed and/or claimed inventive concept(s) provides a radiation sensitive device for detection or measurement of radiation comprising a substrate coated with a radiation sensitive composition comprising a component (a), a component (b), a component (c), and a component (d) wherein the component (a) is a metal compound or a metalloid compound, the component (b) is at least one different metal compound or metalloid compound, the component (c) is at least one functionalized or unfunctionalized acetylenic compound, and the component (d) is at least one amelioration agent.

In one non-limiting embodiment, the component (a) in the radiation sensitive composition that is coated on the substrate that is a part of the radiation sensitive device is a compound selected from the group consisting of a bismuth compound, a cesium compound, a barium compound, a tungsten compound, and combinations thereof, the component (b) in the radiation sensitive composition that is coated on the substrate that is a part of the radiation sensitive device is a compound selected from the group consisting of an aluminum compound, a lead compound, a silicon compound, and combinations thereof, the component (c) in the radiation sensitive composition that is coated on the substrate that is a part of the radiation sensitive device is at least functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof, and the component (d) in the radiation sensitive composition that is coated on the substrate that is a part of the radiation sensitive device is at least one amelioration agent.

In one non-limiting embodiment, the component (a) in the radiation sensitive composition that is coated on the substrate that is a part of the radiation sensitive device is bismuth oxide, the component (b) in the radiation sensitive composition that is coated on the substrate that is a part of the radiation sensitive device is aluminum oxide, the component (c) in the radiation sensitive composition that is coated on the substrate that is a part of the radiation sensitive device is selected from the group consisting of 10,12-pentacosadiynoic acid, a salt thereof, and combinations thereof, and the component (d) in the radiation sensitive composition that is coated on the substrate that is a part of the radiation sensitive device is at least one amelioration agent.

In one non-limiting embodiment, the device is in the form of a film, fiber, rod, plaque, or block. General methods of preparation of and the common types of radiation sensitive devices can be found in the patent EP1529089 B1 that is herein incorporated by reference in its entirety.

High energy radiations are used in a variety of applications, such as curing of coatings and cross-linking of polymers, recording images and information, radiography, nondestructive testing, and diagnostic and radiation therapy wherein their exposure needs to be monitored. Radiation can be given with the intent of cure as well as being used as a very effective modality of palliative treatment to relieve patients from symptoms caused by the cancer. Further indications of radiation therapy include combination strategies with other treatment modalities such as surgery, chemotherapy, or immunotherapy. If used before surgery (neoadjuvant therapy), radiation will aim to shrink the tumor. If used after surgery (adjuvant therapy), radiation will destroy microscopic tumor cells that may have been left behind. It is well known that tumors differ in their sensitivity to radiation treatment.

In one non-limiting embodiment, the radiation sensitive compositions according to the claimed and/or disclosed inventive concept(s) are used for detection and/or measurement of radiation in dental, non-destructive testing, oncological, radiological or radiotherapeutic applications.

In one non-limiting embodiment, the substrate coated with radiation sensitive composition according to the claimed and/or disclosed inventive concept(s) is used for detection and/or measurement of radiation in dental, non-destructive testing, oncological, radiological or radiotherapeutic applications.

In one non-limiting embodiment, the radiation sensitive device for detection or measurement of radiation comprising a substrate coated with a radiation sensitive composition according to the claimed and/or disclosed inventive concept(s) is used for detection and/or measurement of radiation in dental, non-destructive testing, oncological, radiological or radiotherapeutic applications.

Non-limiting examples of oncological, radiological or radiotherapeutic applications include radiation therapy, surgery, chemotherapy, immunotherapy, and hormonal therapy. Non-limiting examples of cancers curable with radiation therapy either alone or in combination with other modalities include skin cancer, prostate carcinomas, lung carcinomas, cervix carcinomas, lymphomas (Hodgkin's and low grade Non-Hodgkin's), head and neck carcinomas, breast carcinomas, rectal and anal carcinomas, local advanced cervix carcinomas, bladder carcinomas, endometrial carcinomas, CNS tumors, soft tissue sarcomas, and pediatric tumors. More information on cancer and radiation therapy and its current advances and future directions can be found in Baskar et al., Int J Med Sci, 2012 (9), 193-199 that is herein incorporated in its entirety by reference. Monitoring of the oral cavity and dental health is required during radiation therapy, particularly of the head and neck, to decrease the severity of the side effects.

In one non-limiting embodiment, the method of measurement and/or detection of radiation using the radiation sensitive device according to the claimed and/or disclosed inventive concept(s) is non-destructive in nature. In general, in the fields of radiology and radiography, non-destructive detection, testing and/or measuring methods are those that help to maintain the integrity and properties of materials or components that are exposed to radiation without causing undue damage to the tested object.

In a sixth aspect, the disclosed and/or claimed inventive concept(s) provides a method for coating a radiation sensitive composition comprising the steps of selecting a substrate that is compatible with the composition, preparing the substrate for said composition to be applied onto it, applying the composition on said substrate after the step of preparing, optionally exposing the substrate after the step of applying, and optionally developing the substrate after the step of exposing, wherein the radiation sensitive composition comprises a component (a), a component (b), a component (c), and a component (d) wherein the component (a) is a metal compound or a metalloid compound, the component (b) is at least one different metal compound or metalloid compound, the component (c) is at least one functionalized or unfunctionalized acetylenic compound, and the component (d) is at least one amelioration agent.

In one non-limiting embodiment, the method for coating a radiation sensitive composition comprises the steps of selecting a substrate that is compatible with the composition, preparing the substrate for said composition to be applied onto it, applying the composition on said substrate after the step of preparing, optionally exposing the substrate after the step of applying, and optionally developing the substrate after the step of exposing, wherein the radiation sensitive composition comprises as component (a), a compound selected from the group consisting of a bismuth compound, a cesium compound, a barium compound, a tungsten compound, and combinations thereof; as component (b), a compound selected from the group consisting of an aluminum compound, a lead compound, a silicon compound, and combinations thereof; as component (c), at least one functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof; and as component (d) at least one amelioration agent.

In one non-limiting embodiment, the method for coating a radiation sensitive composition comprises the steps of selecting a substrate that is compatible with the composition, preparing the substrate for said composition to be applied onto it, applying the composition on said substrate after the step of preparing, optionally exposing the substrate after the step of applying, and optionally developing the substrate after the step of exposing, wherein the radiation sensitive composition comprises as component (a), bismuth oxide; as component (b), aluminum oxide; as component (c), a functionalized acetylenic compound selected from the group consisting of 10,12-pentacosadiynoic acid, a salt thereof, and combinations thereof; and as component (d) at least one amelioration agent.

In one non-limiting embodiment, the method for coating is selected from the group consisting of roll coating, slide coating, curtain coating, rod coating, knife coating, air knife coating, spin coating, dip coating, slit coating, or inkjet coating.

Details of the different methods of coating as per the disclosed and/or claimed inventive concepts can be found in the books (i) Coating and Drying Defects: Troubleshooting Operating Problems, 2nd Edition (2006), edited by Gutoff E. B. and Cohen E. D., and (ii) Liquid Film Coating, Scientific Principles and Their Technological Implications (2012), Edited by Schweizer P. M., the contents of each of which are herein incorporated in its entirety by reference.

In a seventh aspect, the disclosed and/or claimed inventive concept(s) provides a process for preparing a printable substrate comprising the steps of providing a substrate, optionally applying on the substrate a layer serving as a base layer, and applying on the substrate or the base layer at least one layer of a radiation sensitive composition comprising a component (a), a component (b), a component (c), and a component (d) wherein the component (a) is a metal compound or a metalloid compound, the component (b) is at least one different metal compound or metalloid compound, the component (c) is at least one functionalized or unfunctionalized acetylenic compound, and the component (d) is at least one amelioration agent.

In one non-limiting embodiment, the process for preparing a printable substrate comprising the steps of providing a substrate, optionally applying on the substrate a layer serving as a base layer, and applying on the substrate or the base layer at least one layer of a radiation sensitive composition, wherein the radiation sensitive composition comprises as component (a), a compound selected from the group consisting of a bismuth compound, a cesium compound, a barium compound, a tungsten compound, and combinations thereof; as component (b), a compound selected from the group consisting of an aluminum compound, a lead compound, a silicon compound, and combinations thereof; as component (c), at least one functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof; and as component (d) at least one amelioration agent.

In one non-limiting embodiment, the process for preparing a printable substrate comprising the steps of providing a substrate, optionally applying on the substrate a layer serving as a base layer, and applying on the substrate or the base layer at least one layer of a radiation sensitive composition, wherein the radiation sensitive composition comprises as component (a), bismuth oxide; as component (b), aluminum oxide; as component (c), a functionalized acetylenic compound selected from the group consisting of 10,12-pentacosadiynoic acid, a salt thereof, and combinations thereof; and as component (d) at least one amelioration agent.

The compositions according to the disclosed and/or claimed inventive concept(s) may be prepared according to the examples set out below. These examples are presented herein for purposes of illustration of the disclosed and/or claimed inventive concept(s) and are not intended to be limiting, for example, the preparations of the adducts and compositions.

### EXAMPLES

### Example 1

A dispersion of an acetylenic compound such as lithium salt of 10,12-pentacosadiynoic acid (10.5 g) was mixed with an aqueous dispersion comprising bismuth oxide (0.211 kg) and aluminum oxide (0.014 kg), an aqueous solution comprising an amelioration agent such as surfactant (Triton X-100) (0.70 kg), an aqueous solution of a dye such as Sensient Yellow (0.5 kg), and an aqueous solution of a vinyl polymer (0.736 kg). Sufficient amount of deionized water was added to the combined dispersions to make up the quantity of the composition to 21.4 g that was used as a radiation sensitive coating composition.

### Examples 2-97

The method in Example 1 is repeated with different combinations of the composition ingredients to obtain the final radiation sensitive coating compositions. The recipes for each of the examples 2-97 are provided in Table 1-3. The amounts of the amelioration agents such as the dye, the surfactant, and the vinyl polymer are identical to that provided in Example 1. The units of the measures provided in Table 1-3 for all ingredients are consistent with that in Example 1. Herein, the following abbreviations are used:
PCDA: 10,12-pentacosadiynoic acid; HDDA: 5,7-hexadecadiynoic acid; TCDA: 10,12-tricosadiynoic acid; ODDA: 9,12-octadecadiynoic acid; B: bismuth oxide; T: tungsten oxide; C: cesium oxide; B: barium sulfate; A: aluminum oxide; S: silica; L: lead oxide.

Table 1. Exemplary radiation sensitive compositions 2-33 according to the disclosed and/or claimed inventive concepts.

TABLE 1
Exemplary radiation sensitive compositions 2-33 according
to the disclosed and/or claimed inventive concepts.

| Ex. | PCDA | HDDA | TCDA | ODDA | B | T | C | B | A | S | L |
|---|---|---|---|---|---|---|---|---|---|---|---|
| 2 | 10.5 | 0 | 0 | 0 | 0.211 | 0 | 0 | 0 | 0.014 | 0 | 0 |
| 3 | 10.5 | 0 | 0 | 0 | 0 | 0.105 | 0 | 0 | 0.014 | 0 | 0 |
| 4 | 10.5 | 0 | 0 | 0 | 0 | 0 | 0.128 | 0 | 0.014 | 0 | 0 |
| 5 | 10.5 | 0 | 0 | 0 | 0 | 0 | 0 | 0.106 | 0.014 | 0 | 0 |
| 6 | 10.5 | 0 | 0 | 0 | 0.211 | 0 | 0 | 0 | 0 | 0.008 | 0 |
| 7 | 10.5 | 0 | 0 | 0 | 0 | 0.105 | 0 | 0 | 0 | 0.008 | 0 |
| 8 | 10.5 | 0 | 0 | 0 | 0 | 0 | 0.128 | 0 | 0 | 0.008 | 0 |
| 9 | 10.5 | 0 | 0 | 0 | 0 | 0 | 0 | 0.106 | 0 | 0.008 | 0 |
| 10 | 10.5 | 0 | 0 | 0 | 0.211 | 0 | 0 | 0 | 0 | 0 | 0.031 |
| 11 | 10.5 | 0 | 0 | 0 | 0 | 0.105 | 0 | 0 | 0 | 0 | 0.031 |
| 12 | 10.5 | 0 | 0 | 0 | 0 | 0 | 0.128 | 0 | 0 | 0 | 0.031 |
| 13 | 10.5 | 0 | 0 | 0 | 0 | 0 | 0 | 0.106 | 0 | 0 | 0.031 |
| 14 | 10.5 | 0 | 0 | 0 | 0.211 | 0 | 0 | 0 | 0.007 | 0.004 | 0 |
| 15 | 10.5 | 0 | 0 | 0 | 0 | 0.105 | 0 | 0 | 0.007 | 0.004 | 0 |
| 16 | 10.5 | 0 | 0 | 0 | 0 | 0 | 0.128 | 0 | 0.007 | 0.004 | 0 |
| 17 | 10.5 | 0 | 0 | 0 | 0 | 0 | 0 | 0.106 | 0.007 | 0.004 | 0 |
| 18 | 10.5 | 0 | 0 | 0 | 0.211 | 0 | 0 | 0 | 0.007 | 0 | 0.015 |
| 19 | 10.5 | 0 | 0 | 0 | 0 | 0.105 | 0 | 0 | 0.007 | 0 | 0.015 |
| 20 | 10.5 | 0 | 0 | 0 | 0 | 0 | 0.128 | 0 | 0.007 | 0 | 0.015 |
| 21 | 10.5 | 0 | 0 | 0 | 0 | 0 | 0 | 0.106 | 0.007 | 0 | 0.015 |
| 22 | 10.5 | 0 | 0 | 0 | 0.211 | 0 | 0 | 0 | 0 | 0.004 | 0.015 |
| 23 | 10.5 | 0 | 0 | 0 | 0 | 0.105 | 0 | 0 | 0 | 0.004 | 0.015 |
| 24 | 10.5 | 0 | 0 | 0 | 0 | 0 | 0.128 | 0 | 0 | 0.004 | 0.015 |
| 25 | 10.5 | 0 | 0 | 0 | 0 | 0 | 0 | 0.106 | 0 | 0.004 | 0.015 |
| 26 | 0 | 10.5 | 0 | 0 | 0.211 | 0 | 0 | 0 | 0.014 | 0 | 0 |
| 27 | 0 | 10.5 | 0 | 0 | 0 | 0.105 | 0 | 0 | 0.014 | 0 | 0 |
| 28 | 0 | 10.5 | 0 | 0 | 0 | 0 | 0.128 | 0 | 0.014 | 0 | 0 |
| 29 | 0 | 10.5 | 0 | 0 | 0 | 0 | 0 | 0.106 | 0.014 | 0 | 0 |
| 30 | 0 | 10.5 | 0 | 0 | 0.211 | 0 | 0 | 0 | 0 | 0.008 | 0 |
| 31 | 0 | 10.5 | 0 | 0 | 0 | 0.105 | 0 | 0 | 0 | 0.008 | 0 |
| 32 | 0 | 10.5 | 0 | 0 | 0 | 0 | 0.128 | 0 | 0 | 0.008 | 0 |
| 33 | 0 | 10.5 | 0 | 0 | 0 | 0 | 0 | 0.106 | 0 | 0.008 | 0 |

TABLE 2
Exemplary radiation sensitive compositions 34-65 according
to the disclosed and/or claimed inventive concepts.

| Ex. | PCDA | HDDA | TCDA | ODDA | B | T | C | B | A | S | L |
|---|---|---|---|---|---|---|---|---|---|---|---|
| 34 | 0 | 10.5 | 0 | 0 | 0.211 | 0 | 0 | 0 | 0 | 0 | 0.031 |
| 35 | 0 | 10.5 | 0 | 0 | 0 | 0.105 | 0 | 0 | 0 | 0 | 0.031 |
| 36 | 0 | 10.5 | 0 | 0 | 0 | 0 | 0.128 | 0 | 0 | 0 | 0.031 |
| 37 | 0 | 10.5 | 0 | 0 | 0 | 0 | 0 | 0.106 | 0 | 0 | 0.031 |
| 38 | 0 | 10.5 | 0 | 0 | 0.211 | 0 | 0 | 0 | 0.007 | 0.004 | 0 |
| 39 | 0 | 10.5 | 0 | 0 | 0 | 0.105 | 0 | 0 | 0.007 | 0.004 | 0 |
| 40 | 0 | 10.5 | 0 | 0 | 0 | 0 | 0.128 | 0 | 0.007 | 0.004 | 0 |
| 41 | 0 | 10.5 | 0 | 0 | 0 | 0 | 0 | 0.106 | 0.007 | 0.004 | 0 |
| 42 | 0 | 10.5 | 0 | 0 | 0.211 | 0 | 0 | 0 | 0.007 | 0 | 0.015 |
| 43 | 0 | 10.5 | 0 | 0 | 0 | 0.105 | 0 | 0 | 0.007 | 0 | 0.015 |
| 44 | 0 | 10.5 | 0 | 0 | 0 | 0 | 0.128 | 0 | 0.007 | 0 | 0.015 |
| 45 | 0 | 10.5 | 0 | 0 | 0 | 0 | 0 | 0.106 | 0.007 | 0 | 0.015 |
| 46 | 0 | 10.5 | 0 | 0 | 0.211 | 0 | 0 | 0 | 0 | 0.004 | 0.015 |
| 47 | 0 | 10.5 | 0 | 0 | 0 | 0.105 | 0 | 0 | 0 | 0.004 | 0.015 |
| 48 | 0 | 10.5 | 0 | 0 | 0 | 0 | 0.128 | 0 | 0 | 0.004 | 0.015 |
| 49 | 0 | 10.5 | 0 | 0 | 0 | 0 | 0 | 0.106 | 0 | 0.004 | 0.015 |
| 50 | 0 | 0 | 10.5 | 0 | 0.211 | 0 | 0 | 0 | 0.014 | 0 | 0 |
| 51 | 0 | 0 | 10.5 | 0 | 0 | 0.105 | 0 | 0 | 0.014 | 0 | 0 |
| 52 | 0 | 0 | 10.5 | 0 | 0 | 0 | 0.128 | 0 | 0.014 | 0 | 0 |
| 53 | 0 | 0 | 10.5 | 0 | 0 | 0 | 0 | 0.106 | 0.014 | 0 | 0 |
| 54 | 0 | 0 | 10.5 | 0 | 0.211 | 0 | 0 | 0 | 0 | 0.008 | 0 |
| 55 | 0 | 0 | 10.5 | 0 | 0 | 0.105 | 0 | 0 | 0 | 0.008 | 0 |
| 56 | 0 | 0 | 10.5 | 0 | 0 | 0 | 0.128 | 0 | 0 | 0.008 | 0 |
| 57 | 0 | 0 | 10.5 | 0 | 0 | 0 | 0 | 0.106 | 0 | 0.008 | 0 |
| 58 | 0 | 0 | 10.5 | 0 | 0.211 | 0 | 0 | 0 | 0 | 0 | 0.031 |
| 59 | 0 | 0 | 10.5 | 0 | 0 | 0.105 | 0 | 0 | 0 | 0 | 0.031 |
| 60 | 0 | 0 | 10.5 | 0 | 0 | 0 | 0.128 | 0 | 0 | 0 | 0.031 |
| 61 | 0 | 0 | 10.5 | 0 | 0 | 0 | 0 | 0.106 | 0 | 0 | 0.031 |
| 62 | 0 | 0 | 10.5 | 0 | 0.211 | 0 | 0 | 0 | 0.007 | 0.004 | 0 |
| 63 | 0 | 0 | 10.5 | 0 | 0 | 0.105 | 0 | 0 | 0.007 | 0.004 | 0 |
| 64 | 0 | 0 | 10.5 | 0 | 0 | 0 | 0.128 | 0 | 0.007 | 0.004 | 0 |
| 65 | 0 | 0 | 10.5 | 0 | 0 | 0 | 0 | 0.106 | 0.007 | 0.004 | 0 |

TABLE 3
Exemplary radiation sensitive compositions 66-97 according
to the disclosed and/or claimed inventive concepts.

| Ex. | PCDA | HDDA | TCDA | ODDA | B | T | C | B | A | S | L |
|---|---|---|---|---|---|---|---|---|---|---|---|
| 66 | 0 | 0 | 10.5 | 0 | 0.211 | 0 | 0 | 0 | 0.007 | 0 | 0.015 |
| 67 | 0 | 0 | 10.5 | 0 | 0 | 0.105 | 0 | 0 | 0.007 | 0 | 0.015 |
| 68 | 0 | 0 | 10.5 | 0 | 0 | 0 | 0.128 | 0 | 0.007 | 0 | 0.015 |
| 69 | 0 | 0 | 10.5 | 0 | 0 | 0 | 0 | 0.106 | 0.007 | 0 | 0.015 |
| 70 | 0 | 0 | 10.5 | 0 | 0.211 | 0 | 0 | 0 | 0 | 0.004 | 0.015 |
| 71 | 0 | 0 | 10.5 | 0 | 0 | 0.105 | 0 | 0 | 0 | 0.004 | 0.015 |
| 72 | 0 | 0 | 10.5 | 0 | 0 | 0 | 0.128 | 0 | 0 | 0.004 | 0.015 |
| 73 | 0 | 0 | 10.5 | 0 | 0 | 0 | 0 | 0.106 | 0 | 0.004 | 0.015 |
| 74 | 0 | 0 | 0 | 10.5 | 0.211 | 0 | 0 | 0 | 0.014 | 0 | 0 |
| 75 | 0 | 0 | 0 | 10.5 | 0 | 0.105 | 0 | 0 | 0.014 | 0 | 0 |
| 76 | 0 | 0 | 0 | 10.5 | 0 | 0 | 0.128 | 0 | 0.014 | 0 | 0 |
| 77 | 0 | 0 | 0 | 10.5 | 0 | 0 | 0 | 0.106 | 0.014 | 0 | 0 |
| 78 | 0 | 0 | 0 | 10.5 | 0.211 | 0 | 0 | 0 | 0 | 0.008 | 0 |
| 79 | 0 | 0 | 0 | 10.5 | 0 | 0.105 | 0 | 0 | 0 | 0.008 | 0 |
| 80 | 0 | 0 | 0 | 10.5 | 0 | 0 | 0.128 | 0 | 0 | 0.008 | 0 |
| 81 | 0 | 0 | 0 | 10.5 | 0 | 0 | 0 | 0.106 | 0 | 0.008 | 0 |
| 82 | 0 | 0 | 0 | 10.5 | 0.211 | 0 | 0 | 0 | 0 | 0 | 0.031 |
| 83 | 0 | 0 | 0 | 10.5 | 0 | 0.105 | 0 | 0 | 0 | 0 | 0.031 |
| 84 | 0 | 0 | 0 | 10.5 | 0 | 0 | 0.128 | 0 | 0 | 0 | 0.031 |
| 85 | 0 | 0 | 0 | 10.5 | 0 | 0 | 0 | 0.106 | 0 | 0 | 0.031 |
| 86 | 0 | 0 | 0 | 10.5 | 0.211 | 0 | 0 | 0 | 0.007 | 0.004 | 0 |
| 87 | 0 | 0 | 0 | 10.5 | 0 | 0.105 | 0 | 0 | 0.007 | 0.004 | 0 |
| 88 | 0 | 0 | 0 | 10.5 | 0 | 0 | 0.128 | 0 | 0.007 | 0.004 | 0 |
| 89 | 0 | 0 | 0 | 10.5 | 0 | 0 | 0 | 0.106 | 0.007 | 0.004 | 0 |
| 90 | 0 | 0 | 0 | 10.5 | 0.211 | 0 | 0 | 0 | 0.007 | 0 | 0.015 |
| 91 | 0 | 0 | 0 | 10.5 | 0 | 0.105 | 0 | 0 | 0.007 | 0 | 0.015 |
| 92 | 0 | 0 | 0 | 10.5 | 0 | 0 | 0.128 | 0 | 0.007 | 0 | 0.015 |
| 93 | 0 | 0 | 0 | 10.5 | 0 | 0 | 0 | 0.106 | 0.007 | 0 | 0.015 |
| 94 | 0 | 0 | 0 | 10.5 | 0.211 | 0 | 0 | 0 | 0 | 0.004 | 0.015 |
| 95 | 0 | 0 | 0 | 10.5 | 0 | 0.105 | 0 | 0 | 0 | 0.004 | 0.015 |
| 96 | 0 | 0 | 0 | 10.5 | 0 | 0 | 0.128 | 0 | 0 | 0.004 | 0.015 |
| 97 | 0 | 0 | 0 | 10.5 | 0 | 0 | 0 | 0.106 | 0 | 0.004 | 0.015 |

What is claimed is:

1. A radiation-sensitive coating composition comprising a component (a) and a component (b) wherein said component (a) is a metal compound or a metalloid compound and said component (b) is at least one different metal compound or metalloid compound.

2. The radiation-sensitive coating composition according to claim 1, wherein said component (a) is a compound selected from the group consisting of a bismuth compound, a cesium compound, a barium compound, a tungsten compound, and combinations thereof, and said component (b) is a compound selected from the group consisting of an aluminum compound, a lead compound, a silicon compound, and combinations thereof;
wherein said component (a) is a bismuth compound and said component (b) is a compound selected from the group consisting of an aluminum compound, a lead compound, a silicon compound, and combinations thereof; or
wherein said component (a) is a bismuth compound and said component (b) is an aluminum compound; and still said component (a) is bismuth oxide and said component (b) is aluminum oxide.

3. The radiation-sensitive coating composition according to claim 1, wherein said component (b) is a compound selected from the group consisting of an aluminum compound, a lead compound, a silicon compound, and combinations thereof;
wherein said radiation comprises ionizing radiation or electromagnetic radiation; or
wherein said ionizing radiation comprises alpha rays, beta rays, or neutron rays; or
wherein said electromagnetic radiation comprises visible radiation, ultraviolet radiation, infrared radiation, X-rays, or gamma rays.

4. (canceled)

5. (canceled)

6. (canceled)

7. The radiation-sensitive coating composition according to claim 2, wherein said bismuth compound is selected from the group consisting of bismuth oxide, bismuth chloride oxide, bismuth sulfide, bismuth hydroxide, bismuth carbonate, bismuth silicate, bismuth subcarbonate, bismuth selenide, bismuth telluride, bismuth chalconides, bismuth fluoride, bismuth chloride, bismuth bromide, bismuth iodide, bismuth salts, bismuth complexes, bismuth alloys, bismuth vanadate, bismuth orthovanadate, bismuth vanadate molybdate, bismuth nitrate, bismuth manganese oxide, bismuth oxide iodide, bismuth oxide bromide, and combinations thereof.

8. The radiation-sensitive coating composition according to claim 2, wherein said cesium compound is selected from the group consisting of cesium chloride, cesium bitartrate, cesium halide, cesium polyhalide, cesium polyiodide, cesium oxide, cesium sulfide, cesium polysulfide, cesium carbonate, and combinations thereof; or wherein said barium compound is selected from the group consisting of barium sulfate, barium oxide, barium dithionate, and combinations thereof; or
wherein said tungsten compound is selected from the group consisting of tungsten carbide, tungsten oxide, and combinations thereof; or
wherein said aluminum compound is selected from the group consisting of aluminum oxide, aluminum sulfate, aluminum potassium sulfate, and combinations thereof; or
wherein said lead compound is selected from the group consisting of lead salts, lead sulfate, lead chloride, lead bromide, lead oxide, lead iodide, and combinations thereof; or
wherein said silicon compound is selected from the group consisting of silicon dioxide, silica, fumed silica, silica gel, aerogel, precipitated silica, and combinations thereof

9. (canceled)

10. (canceled)

11. (canceled)

12. (canceled)

13. (canceled)

14. (canceled)

15. (canceled)

16. (canceled)

17. The radiation-sensitive coating composition according to claim 2, wherein said bismuth compound is selected from the group consisting of bismuth oxide, bismuth chloride oxide, bismuth sulfide, bismuth hydroxide, bismuth carbonate, bismuth silicate, bismuth subcarbonate, bismuth selenide, bismuth telluride, bismuth chalconides, bismuth fluoride, bismuth chloride, bismuth bromide, bismuth iodide, bismuth salts, bismuth complexes, bismuth alloys, bismuth vanadate, bismuth orthovanadate, bismuth vanadate molybdate, bismuth nitrate, bismuth manganese oxide, bismuth oxide iodide, bismuth oxide bromide, and combinations thereof, and said aluminum compound is selected from the group consisting of aluminum oxide, aluminum sulfate, aluminum potassium sulfate, and combinations thereof.

18. (canceled)

19. A radiation-sensitive composition comprising a component (a), a component (b), and a component (c) wherein said component (a) is a metal compound or a metalloid compound, said component (b) is at least one different metal compound or metalloid compound, and said component (c) is at least one functionalized or unfunctionalized acetylenic compound, wherein said component (a) is selected from the group consisting of bismuth compounds, cesium compounds, barium compounds, tungsten compounds, and combinations thereof; or
wherein said component (b) is a compound selected from the group consisting of an aluminum compound, a lead compound, a silicon compound, and combinations thereof; or wherein said bismuth compound is selected from the group consisting of bismuth oxide, bismuth chloride oxide, bismuth sulfide, bismuth hydroxide, bismuth carbonate, bismuth silicate, bismuth subcarbonate, bismuth selenide, bismuth telluride, bismuth chalconides, bismuth fluoride, bismuth chloride, bismuth bromide, bismuth iodide, bismuth salts, bismuth complexes, bismuth alloys, bismuth vanadate, bismuth orthovanadate, bismuth vanadate molybdate, bismuth nitrate, bismuth manganese oxide, bismuth oxide iodide, bismuth oxide bromide, and combinations thereof.

20. (canceled)

21. (canceled)

22. (canceled)

23. The radiation-sensitive composition according to claim 19, wherein said cesium compound is selected from the group consisting of cesium chloride, cesium bitartrate, cesium halide, cesium polyhalide, cesium polyiodide, cesium oxide, cesium sulfide, cesium polysulfide, cesium carbonate, and combinations thereof; or
wherein said barium compound is selected from the group consisting of barium sulfate, barium oxide, barium dithionate, and combinations thereof; or
wherein said tungsten compound is selected from the group consisting of tungsten carbide, tungsten oxide, and combinations thereof; or
wherein said aluminum compound is selected from the group consisting of aluminum oxide, aluminum sulfate, aluminum potassium sulfate, and combinations thereof; or
wherein said lead compound is selected from the group consisting of lead salts, lead sulfate, lead chloride, lead bromide, lead oxide, lead iodide, and combinations thereof; or
wherein said silicon compound is selected from the group consisting of silicon dioxide, silica, fumed silica, silica gel, aerogel, precipitated silica, and combinations thereof.

24. (canceled)

25. (canceled)

26. (canceled)

27. (canceled)

28. (canceled)

29. The radiation-sensitive composition according to claim 19, wherein said component (a) is a compound selected from the group consisting of a bismuth compound, a cesium compound, a barium compound, a tungsten compound, and combinations thereof, said component (b) is a compound selected from the group consisting of an aluminum compound, a lead compound, a silicon compound, and combinations thereof, and said component (c) is at least one functionalized or unfunctionalized acetylenic compound;
wherein said component (a) is a bismuth compound, said component (b) is a compound selected from the group consisting of an aluminum compound, a lead compound, a silicon compound, and combinations thereof, and said component (c) is at least one functionalized or unfunctionalized acetylenic compound; or
wherein said component (a) is a bismuth compound, said component (b) is an aluminum compound, and said component (c) is at least one functionalized or unfunctionalized acetylenic compound; or
wherein said bismuth compound is selected from the group consisting of bismuth oxide, bismuth chloride oxide, bismuth sulfide, bismuth hydroxide, bismuth carbonate, bismuth silicate, bismuth subcarbonate, bismuth selenide, bismuth telluride, bismuth chalconides, bismuth fluoride, bismuth chloride, bismuth bromide, bismuth iodide, bismuth salts, bismuth complexes, bismuth alloys, bismuth vanadate, bismuth orthovanadate, bismuth vanadate molybdate, bismuth nitrate, bismuth manganese oxide, bismuth oxide iodide, bismuth oxide bromide, and combinations thereof, and said aluminum compound is selected from the group consisting of aluminum oxide, aluminum sulfate, aluminum potassium sulfate, and combinations thereof; or
wherein said component © is a functionalized acetylenic compound comprising an acetylene moiety and at least one non-acetylenic functional group; or
wherein said non-acetylenic functional group is selected from the group consisting of carboxyl, carboxylate, hydroxy, hydroxide, alkoxy, alkoxide, epoxy, amino, ammonium, aldehyde, keto, amide, ester, nitrile, urethane, ether, and combinations thereof; or

30. (canceled)

31. (canceled)

32. (canceled)

33. (canceled)

34. (canceled)

35. (canceled)

36. The radiation-sensitive composition according to claim 19, wherein said component (c) is a functionalized acetylenic compound comprising at least two acetylene moieties and at least one non-acetylenic functional group; or
wherein said non-acetylenic functional group is selected from the group consisting of carboxyl, carboxylate, hydroxy, hydroxide, alkoxy, alkoxide, epoxy, amino, ammonium, aldehyde, keto, amide, ester, nitrile, urethane, ether, and combinations thereof; or
wherein said non-acetylenic functional group is selected from the group consisting of carboxyl, carboxylate, and combinations thereof.

37. (canceled)

38. (canceled)

39. The radiation-sensitive composition according to claim 36 wherein said component (c) is a functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof; or
wherein said component (c) is 10,12-pentacosadiynoic acid or a salt thereof; or
wherein said component (a) is a compound selected from the group consisting of a bismuth compound, a cesium compound, a barium compound, a tungsten compound, and combinations thereof, said component (b) is a compound selected from the group consisting of an aluminum compound, a lead compound, a silicon compound, and combinations thereof, and said component (c) is at least one functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof; or
wherein said component (a) is a bismuth compound, said component (b) is a compound selected from the group consisting of an aluminum compound, a lead compound, a silicon compound, and combinations thereof, and said component (c) is at least one functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof.

40. (canceled)

41. (canceled)

42. The radiation-sensitive composition according to claim 39, wherein said component (a) is a bismuth compound, said component (b) is a compound selected from the group consisting of an aluminum compound, a lead compound, a silicon compound, and combinations thereof, and said component (c) is at least one functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof; or
wherein said component (a) is a bismuth compound, said component (b) is a an aluminum compound, and said component (c) is at least one functionalized acetylenic compound selected from the group consisting of decadiynoic acids, undecadiynoic acids. dodecadiynoic acids, tridecadiynoic acids, tetradecadiynoic acids, pentadecadiynoic acids. hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof; or
wherein said component (c) is 10,12-pentacosadiynoic acid or a salt thereof; or
wherein said component (a) is bismuth oxide, said component (b) is aluminum oxide, and said component (c) is selected from the group consisting of 10,12-pentacosadiynoic acid, a salt thereof, and combinations thereof.

43. (canceled)

44. (canceled)

45. (canceled)

46. A radiation-sensitive composition comprising a component (a), a component (b), a component (c), and a component (d) wherein said component (a) is a metal compound or a metalloid compound, said component (b) is at least one different metal compound or metalloid compound, said component (c) is at least one functionalized or unfunctionalized acetylenic compound, and said component (d) is at least one amelioration agent;
wherein said component (a) is selected from the group consisting of bismuth compounds, cesium compounds, barium compounds, tungsten compounds, and combinations thereof; or
wherein said component (b) is a compound selected from the group consisting of an aluminum compound, a lead compound, a silicon compound, and combinations thereof; or
wherein said bismuth compound is selected from the group consisting of bismuth oxide, bismuth chloride oxide, bismuth sulfide, bismuth hydroxide, bismuth carbonate, bismuth silicate, bismuth subcarbonate, bismuth selenide, bismuth telluride, bismuth chalconides, bismuth fluoride, bismuth chloride, bismuth bromide, bismuth iodide, bismuth salts, bismuth complexes, bismuth alloys, bismuth vanadate, bismuth orthovanadate, bismuth vanadate molybdate, bismuth nitrate, bismuth manganese oxide, bismuth oxide iodide, bismuth oxide bromide, and combinations thereof; or
wherein said cesium compound is selected from the group consisting of cesium chloride, cesium bitartrate, cesium halide, cesium polyhalide, cesium polyiodide, cesium oxide, cesium sulfide, cesium polysulfide, cesium carbonate, and combinations thereof.

47. (canceled)

48. (canceled)

49. (canceled)

50. (canceled)

51. The radiation-sensitive composition according to claim 46, wherein said barium compound is selected from the group consisting of barium sulfate, barium oxide, barium dithionate, and combinations thereof; or
wherein said tungsten compound is selected from the group consisting of tungsten carbide, tungsten oxide, and combinations thereof.

52. (canceled)

53. The radiation-sensitive composition according to claim 46, wherein said aluminum compound is selected from the group consisting of aluminum oxide, aluminum sulfate, aluminum potassium sulfate, and combinations thereof; or
wherein said lead compound is selected from the group consisting of lead salts, lead sulfate, lead chloride, lead bromide, lead oxide, lead iodide, and combinations thereof; or
wherein said silicon compound is selected from the group consisting of silicon dioxide, silica, fumed silica, silica gel, aerogel, precipitated silica, and combinations thereof.

54. (canceled)

55. (canceled)

56. The radiation-sensitive composition according to claim 46 wherein said component (a) is a compound selected from the group consisting of a bismuth compound, a cesium compound, a barium compound, a tungsten compound, and combinations thereof, said component (b) is a compound selected from the group consisting of an aluminum compound, a lead compound, a silicon compound, and combinations thereof, said component (c) is at least one functionalized or unfunctionalized acetylenic compound, and said component (d) is at least one amelioration agent;
wherein said component (a) is a bismuth compound, said component (b) is a compound selected from the group consisting of an aluminum compound, a lead compound, a silicon compound, and combinations thereof, said component (c) is at least one functionalized or unfunctionalized acetylenic compound, and said component (d) is at least one amelioration agent; or
wherein said component (a) is a bismuth compound, said component (b) is an aluminum compound, said component (c) is at least one functionalized or unfunctionalized acetylenic compound, and said component (d) is at least one amelioration agent; or
wherein said bismuth compound is selected from the group consisting of bismuth oxide, bismuth chloride oxide, bismuth sulfide, bismuth hydroxide, bismuth carbonate, bismuth silicate, bismuth subcarbonate, bismuth selenide, bismuth telluride, bismuth chalconides, bismuth fluoride, bismuth chloride, bismuth bromide, bismuth iodide, bismuth salts, bismuth complexes, bismuth alloys, bismuth vanadate, bismuth orthovanadate, bismuth vanadate molybdate, bismuth nitrate, bismuth manganese oxide, bismuth oxide iodide, bismuth oxide bromide, and combinations thereof, and said aluminum compound is selected from the group consisting of aluminum oxide, aluminum sulfate, aluminum potassium sulfate, and combinations thereof; or
wherein said component (a) is bismuth oxide, said component (b) is aluminum oxide, said component (c) is selected from the group consisting of 10,12-pentacosadiynoic acid, a salt thereof, and combinations thereof, and said component (d) is at least one amelioration agent; or
wherein said amelioration agent is selected from the group consisting of adsorption agents, binders, dyes, polymers, shelf-life extenders, solvents, stabilizers, surfactants, and combinations thereof.

57. (canceled)

58. (canceled)

59. (canceled)

60. The radiation-sensitive composition according to claim 46, wherein said component (c) is a functionalized acetylenic compound comprising an acetylene moiety and at least one non-acetylenic functional group; or
wherein said non-acetylenic functional group is selected from the group consisting of carboxyl, carboxylate, hydroxy, hydroxide, alkoxy, alkoxide, epoxy, amino, ammonium, aldehyde, keto, amide, ester, nitrile, urethane, ether, and combinations thereof; or
wherein said non-acetylenic functional group is selected from the group consisting of carboxyl, carboxylate, and combinations thereof; or
wherein said component (c) is a functionalized acetylenic compound comprising at least two acetylene moieties and at least one non-acetylenic functional group.

61. (canceled)

62. (canceled)

63. (canceled)

64. The radiation-sensitive composition according to claim 60, wherein said non-acetylenic functional group is selected from the group consisting of carboxyl, carboxylate, hydroxy, hydroxide, alkoxy, alkoxide, epoxy, amino, ammonium, aldehyde, keto, amide, ester, nitrile, urethane, ether, and combinations thereof,
wherein said non-acetylenic functional group is selected from the group consisting of carboxyl, carboxylate, and combinations thereof; or
wherein said component (c) is a functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof.

65. (canceled)

66. (canceled)

67. The radiation-sensitive composition according to claim 66, wherein said component (c) is 10,12-pentacosadiynoic acid or a salt thereof.

68. The radiation-sensitive composition according to claim 56, wherein said component (a) is a compound selected from the group consisting of a bismuth compound, a cesium compound, a barium compound, a tungsten compound, and combinations thereof, said component (b) is a compound selected from the group consisting of an aluminum compound, a lead compound, a silicon compound, and combinations thereof, said component (c) is at least one functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof, and said component (d) is at least one amelioration agent;
wherein said component (a) is a bismuth compound, said component (b) is a compound selected from the group consisting of an aluminum compound, a lead compound, a silicon compound, and combinations thereof, said component (c) is at least one functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof, and said component (d) is at least one amelioration agent.

69. (canceled)

70. The radiation-sensitive composition according to claim 68, wherein said component (a) is a bismuth compound, said component (b) is a an aluminum compound, said component (c) is at least one functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof, and said component (d) is at least one amelioration agent;
wherein said component (c) is 10,12-pentacosadiynoic acid or a salt thereof; or
wherein said component (a) is bismuth oxide, said component (b) is aluminum oxide, said component (c) is selected from the group consisting of 10,12-pentacosadiynoic acid, a salt thereof, and combinations thereof, and said component (d) is at least one amelioration agent; or
wherein said amelioration agent is selected from the group consisting of adsorption agents, binders, dyes, polymers, shelf-life extenders, solvents, stabilizers, surfactants, and combinations thereof.

71. (canceled)

72. (canceled)

73. (canceled)

74. A substrate coated with a radiation-sensitive composition comprising a component (a), a component (b), a component (c), and a component (d) wherein said component (a) is a metal compound or a metalloid compound, said component (b) is at least one different metal compound or metalloid compound, said component (c) is at least one functionalized or unfunctionalized acetylenic compound, and said component (d) is at least one amelioration agent;
wherein said component (a) is selected from the group consisting of bismuth compounds, cesium compounds, barium compounds, tungsten compounds, and combinations thereof; or
wherein said component (b) is a compound selected from the group consisting of an aluminum compound, a lead compound, a silicon compound, and combinations thereof; or
wherein said bismuth compound is selected from the group consisting of bismuth oxide, bismuth chloride oxide, bismuth sulfide, bismuth hydroxide, bismuth carbonate, bismuth silicate, bismuth subcarbonate, bismuth selenide, bismuth telluride, bismuth chalconides, bismuth fluoride, bismuth chloride, bismuth bromide, bismuth iodide, bismuth salts, bismuth complexes, bismuth alloys, bismuth vanadate, bismuth orthovanadate, bismuth vanadate molybdate, bismuth nitrate, bismuth manganese oxide, bismuth oxide iodide, bismuth oxide bromide, and combinations thereof; or
wherein said cesium compound is selected from the group consisting of cesium chloride, cesium bitartrate, cesium halide, cesium polyhalide, cesium polyiodide, cesium oxide, cesium sulfide, cesium polysulfide, cesium carbonate, and combinations thereof.

75. (canceled)

76. (canceled)

77. (canceled)

78. (canceled)

79. The substrate coated with a radiation-sensitive composition according to claim 75 wherein said barium compound is selected from the group consisting of barium sulfate, barium oxide, barium dithionate, and combinations thereof;
wherein said tungsten compound is selected from the group consisting of tungsten carbide, tungsten oxide, and combinations thereof; or
wherein said aluminum compound is selected from the group consisting of aluminum oxide, aluminum sulfate, aluminum potassium sulfate, and combinations thereof; or
wherein said lead compound is selected from the group consisting of lead salts, lead sulfate, lead chloride, lead bromide, lead oxide, lead iodide, and combinations thereof; or
wherein said silicon compound is selected from the group consisting of silicon dioxide, silica, fumed silica, silica gel, aerogel, precipitated silica, and combinations thereof.

80. (canceled)

81. (canceled)

82. (canceled)

83. (canceled)

84. The substrate coated with a radiation-sensitive composition according to claim 74, wherein said component (a) is a compound selected from the group consisting of a bismuth compound, a cesium compound, a barium compound, a tungsten compound, and combinations thereof, said component (b) is a compound selected from the group consisting of an aluminum compound, a lead compound, a silicon compound, and combinations thereof, said component (c) is at least one functionalized or unfunctionalized acetylenic compound, and said component (d) is at least one amelioration agent; or
wherein said component (a) is a bismuth compound, said component (b) is a compound selected from the group consisting of an aluminum compound, a lead compound, a silicon compound, and combinations thereof, said component (c) is at least one functionalized or unfunctionalized acetylenic compound, and said component (d) is at least one amelioration agent; or
wherein said component (a) is a bismuth compound, said component (b) is an aluminum compound, said component (c) is at least one functionalized or unfunctionalized acetylenic compound, and said component (d) is at least one amelioration agent.

85. (canceled)

86. (canceled)

87. The substrate coated with a radiation-sensitive composition according to claim 84, wherein said bismuth compound is selected from the group consisting of bismuth oxide, bismuth chloride oxide, bismuth sulfide, bismuth hydroxide, bismuth carbonate, bismuth silicate, bismuth subcarbonate, bismuth selenide, bismuth telluride, bismuth chalconides, bismuth fluoride, bismuth chloride, bismuth bromide, bismuth iodide, bismuth salts, bismuth complexes, bismuth alloys, bismuth vanadate, bismuth orthovanadate, bismuth vanadate molybdate, bismuth nitrate, bismuth manganese oxide, bismuth oxide iodide, bismuth oxide bromide, and combinations thereof, and said aluminum compound is selected from the group consisting of aluminum oxide, aluminum sulfate, aluminum potassium sulfate, and combinations thereof.

88. The substrate coated with a radiation-sensitive composition according to claim 74 wherein said component (c) is a functionalized acetylenic compound comprising an acetylene moiety and at least one non-acetylenic functional group;
wherein said non-acetylenic functional group is selected from the group consisting of carboxyl, carboxylate, hydroxy, hydroxide, alkoxy, alkoxide, epoxy, amino, ammonium, aldehyde, keto, amide, ester, nitrile, urethane, ether, and combinations thereof; or
wherein said non-acetylenic functional group is selected from the group consisting of carboxyl, carboxylate, and combinations thereof; or
wherein said component (c) is a functionalized acetylenic compound comprising at least two acetylene moieties and at least one non-acetylenic functional group; or
wherein said non-acetylenic functional group is selected from the group consisting of carboxyl, carboxylate, hydroxy, hydroxide, alkoxy, alkoxide, epoxy, amino, ammonium, aldehyde, keto, amide, ester, nitrile, urethane, ether, and combinations thereof; or
wherein said non-acetylenic functional group is selected from the group consisting of carboxyl, carboxylate, and combinations thereof; or
wherein said component (c) is a functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof; or
wherein said component (c) is 10,12-pentacosadiynoic acid or a salt thereof.

89. (canceled)

90. (canceled)

91. (canceled)

92. (canceled)

93. (canceled)

94. (canceled)

95. (canceled)

96. The substrate coated with a radiation-sensitive composition according to claim 84 wherein said component (a) is a compound selected from the group consisting of a bismuth compound, a cesium compound, a barium compound, a tungsten compound, and combinations thereof, said component (b) is a compound selected from the group consisting of an aluminum compound, a lead compound, a silicon compound, and combinations thereof, said component (c) is at least one functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof, and said component (d) is at least one amelioration agent;
wherein said component (a) is a bismuth compound, said component (b) is a compound selected from the group consisting of an aluminum compound, a lead compound, a silicon compound, and combinations thereof, said component (c) is at least one functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof, and said component (d) is at least one amelioration agent.

97. (canceled)

98. The substrate coated with a radiation-sensitive composition according to claim 96, wherein said component (a) is a bismuth compound, said component (b) is a an aluminum compound, said component (c) is at least one functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof, and said component (d) is at least one amelioration agent; wherein said component (c) is 10,12-pentacosadiynoic acid or a salt thereof.

99. (canceled)

100. The substrate coated with a radiation-sensitive composition according to claim 98 wherein said component (a) is bismuth oxide, said component (b) is aluminum oxide, said component (c) is selected from the group consisting of 10,12-pentacosadiynoic acid, a salt thereof, and combinations thereof, and said component (d) is at least one amelioration agent; wherein said amelioration agent is selected from the group consisting of adsorption agents, binders, dyes, polymers, shelf-life extenders, solvents, stabilizers, surfactants, and combinations thereof; or
wherein said substrate is selected from the group consisting of paper, polymer, plastic, textile, metal, canvas, cloth, wood, leather, ceramic, glass, and combinations thereof.

101. (canceled)

102. (canceled)

103. The substrate coated with a radiation-sensitive composition according to claim 102, wherein said paper is selected from the group consisting of plain paper, coated paper, treated paper, photographic quality paper, and combinations thereof;
wherein said plastic is selected from the group consisting of vinyls, polyurethanes, polycarbonates, polyethers, polyesters, polyvinyl chloride, polystyrene, polyethylene, polyolefins, polyvinyl acetate, silicone rubbers, rubbers, polyester-polyether copolymers, ethylene methacrylate, silicones, nylon, polyamides, and combinations thereof.

104. (canceled)

105. A radiation-sensitive device for detection or measurement of radiation comprising a substrate coated with a radiation sensitive composition comprising a component (a), a component (b), a component (c), and a component (d) wherein said component (a) is a metal compound or a metalloid compound, said component (b) is at least one different metal compound or metalloid compound, said component (c) is at least one functionalized or unfunctionalized acetylenic compound, and said component (d) is at least one amelioration agent; wherein said component (a) is a compound selected from the group consisting of a bismuth compound, a cesium compound, a barium compound, a tungsten compound, and combinations thereof, said component (b) is a compound selected from the group consisting of an aluminum compound, a lead compound, a silicon compound, and combinations thereof, said component (c) is at least one functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids. heptacosadiynoic acids, octacosadiynoic acids, nonacosadiynoic acids, triacontanediynoic acids, salts thereof, and combinations thereof, and said component (d) is at least one amelioration agent; or
wherein said component (a) is bismuth oxide, said component (b) is aluminum oxide, said component (c) is selected from the group consisting of 10,12-pentacosadiynoic acid, a salt thereof, and combinations thereof, and said component (d) is at least one amelioration agent; or
wherein said device is in the form of a film, fiber, rod, plaque, or block.

106. (canceled)

107. (canceled)

108. (canceled)

109. The radiation-sensitive coating composition according to claim 1, wherein the radiation-sensitive coating composition is used in a dental, non-destructive testing, oncological, radiological, or radiotherapeutic application.

110. The radiation-sensitive composition according to claim 46, wherein the radiation-sensitive composition is used in a dental, non-destructive testing, oncological, radiological, or radiotherapeutic application.

111. The substrate coated with a radiation-sensitive composition according to claim 74, wherein the radiation-sensitive composition is used in a dental, non-destructive testing, oncological, radiological, or radiotherapeutic application.

112. The radiation-sensitive device for detection or measurement of radiation according to claim 105 that is used in a dental, non-destructive testing, oncological, radiological, or radiotherapeutic application.

113. A method for coating a radiation-sensitive composition comprising the steps of selecting a substrate that is compatible with said composition, preparing said substrate for said composition to be applied onto it, applying said composition on said substrate after said step of preparing, optionally exposing said substrate after said step of applying, and optionally developing said substrate after said step of exposing, wherein said radiation sensitive composition comprises a component (a), a component (b), a component (c), and a component (d) wherein said component (a) is a metal compound or a metalloid compound, said component (b) is at least one different metal compound or metalloid compound, said component (c) is at least one functionalized or unfunctionalized acetylenic compound, and said component (d) is at least one amelioration agent.

114. The method for coating a radiation-sensitive composition according to claim 113, wherein said component (a) is a compound selected from the group consisting of a bismuth compound, a cesium compound, a barium compound, a tungsten compound, and combinations thereof, said component (b) is a compound selected from the group consisting of an aluminum compound, a lead compound, a silicon compound, and combinations thereof, said component (c) is at least one functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof, and said component (d) is at least one amelioration agent;
wherein said component (a) is bismuth oxide, said component (b) is aluminum oxide, said component (c) is selected from the group consisting of 10,12-pentacosadiynoic acid, a salt thereof, and combinations thereof, and said component (d) is at least one amelioration agent; or
wherein said method for coating is selected from the group consisting of roll coating, slide coating, curtain coating, rod coating, knife coating, air knife coating, spin coating, dip coating, slit coating, or inkjet coating.

115. (canceled)

116. (canceled)

117. A process for preparing a printable substrate comprising the steps of providing a substrate, optionally applying on said substrate a layer serving as a base layer, and applying on said substrate or said base layer at least one layer of a radiation sensitive composition comprising a component (a), a component (b), a component (c), and a component (d) wherein said component (a) is a metal compound or a metalloid compound, said component (b) is at least one different metal compound or metalloid compound, said component (c) is at least one functionalized or unfunctionalized acetylenic compound, and said component (d) is at least one amelioration agent;
wherein said component (a) is a compound selected from the group consisting of a bismuth compound, a cesium compound, a barium compound, a tungsten compound, and combinations thereof, said component (b) is a compound selected from the group consisting of an aluminum compound, a lead compound, a silicon compound, and combinations thereof, said component (c) is at least one functionalized acetylenic compound selected from the group consisting of decadiynoic acids, undecadiynoic acids, dodecadiynoic acids, tridecadiynoic acids, tetradecadiynoic acids, pentadecadiynoic acids, hexadecadiynoic acids, heptadecadiynoic acids, octadecadiynoic acids, nonadecadiynoic acids, icosadiynoic acids, heneicosadiynoic acids, docosadiynoic acids, tricosadiynoic acids, tetracosadiynoic acids, pentacosadiynoic acids, hexacosadiynoic acids, heptacosadiynoic acids, octacosadiynoic acids, nonacosadiynoic acids, triacontanediynoic acids, salts thereof, and combinations thereof, and said component (d) is at least one amelioration agent; or wherein said component (a) is bismuth oxide, said component (b) is aluminum oxide, said component (c) is selected from the group consisting of 10,12-pentacosadiynoic acid, a salt thereof, and combinations thereof, and said component (d) is at least one amelioration agent.

118. (canceled)

119. (canceled)
